(19) United States
(12) Patent Application Publication
(10) Pub. No.: US 2024/0008351 A1
(43) Pub. Date: Jan. 4, 2024

(54) SENSOR EMBEDDED DISPLAY PANEL AND ELECTRONIC DEVICE

(71) Applicant: Samsung Electronics Co., Ltd., Suwon-si (KR)

(72) Inventors: Jisoo SHIN, Suwon-si (KR); Hiromasa SHIBUYA, Suwon-si (KR); Hyeong-ju KIM, Suwon-si (KR); Kyung Bae PARK, Suwon-si (KR); Feifei FANG, Suwon-si (KR); Sungyoung YUN, Suwon-si (KR); Chul Joon HEO, Suwon-si (KR)

(73) Assignee: Samsung Electronics Co., Ltd., Suwon-si (KR)

(21) Appl. No.: 18/065,152

(22) Filed: Dec. 13, 2022

(30) Foreign Application Priority Data
May 31, 2022 (KR) 10-2022-0067158

(51) Int. Cl. H10K 65/00; H10K 85/60; H10K 85/40

(52) U.S. Cl. CPC H01L 27/288; H01L 51/0067; H01L 51/0071; H01L 51/0094; H01L 51/0072

(57) ABSTRACT

Disclosed are a sensor-embedded display panel and an electronic device including the sensor-embedded display panel. The sensor-embedded panel may include a light emitting element and a photosensor on a substrate. The light emitting element may include a light emitting layer and the photosensor may include a photosensitive layer in parallel with the light emitting layer along an in-plane direction of the substrate. The light emitting element and the photosensor include respective portions of a first common auxiliary layer. The first common auxiliary layer may be continuous along the in-place direction of the substrate and under each of the light emitting layer and the photosensitive layer. The photosensitive layer may include a fluorine-containing p-type semiconductor and a non-fullerene n-type semiconductor. The non-fullerene n-type semiconductor may form a pn junction with the p-type semiconductor.

### CROSS-REFERENCE TO RELATED APPLICATION

This application claims priority to and the benefit of Korean Patent Application No. 10-2022-0067158, filed in the Korean Intellectual Property Office on May 31, 2022, the entire contents of which are incorporated herein by reference.

### BACKGROUND

### 1. Field

A sensor-embedded display panel and an electronic device are disclosed.

### 2. Description of the Related Art

Recently, there is an increasing demand for a display device implementing a biometric recognition technology that authenticates the person by extracting specific biometric information or behavioral characteristic information of a person with an automated device centering on finance, healthcare, and mobile. Accordingly, the display device may include a sensor for biometric recognition.

On the other hand, such a sensor for biometric recognition may be divided into an electrostatic type, an ultrasonic type, or an optical type. Among them, the optical type sensor is a sensor that absorbs light and converts it into an electrical signal. The organic material may have a large extinction coefficient and may selectively absorb light in a specific wavelength region according to a molecular structure, and thus it may be usefully applied to an optical type sensor.

### SUMMARY

A sensor provided in a display device may be disposed under the display panel or may be manufactured as a separate module and mounted on the outside of the display panel. However, when the sensor is disposed under the display panel, the object should be recognized through the display panel, various films, and/or parts, and thus performance may be degraded. When the sensor is manufactured and mounted as a separate module, there may be limitations in terms of design and usability. Accordingly, an embedded sensor having a sensor embedded in the display panel may be proposed. However, since the performance and physical properties required for the display panel and the sensor may be different from each other, it may be difficult to implement in an integrated form.

Some example embodiments provide a sensor-embedded display panel including a sensor capable of improving performance by being integrated with the display panel.

Some example embodiments provide an electronic device including the sensor-embedded display panel.

According to an example embodiment, a sensor-embedded display panel may include a substrate; a light emitting element on the substrate, the light emitting element including a light emitting layer, and a photosensor on the substrate, the photosensor including a photosensitive layer in parallel with the light emitting layer along an in-plane direction of the substrate. The light emitting element and the photosensor may include respective portions of a first common auxiliary layer. The first common auxiliary layer may be continuous along the in-plane direction of the substrate and under each of the light emitting layer and the photosensitive layer. The photosensitive layer may include a fluorine-containing p-type semiconductor and a non-fullerene n-type semiconductor. The non-fullerene n-type semiconductor may form a pn junction with the fluorine-containing p-type semiconductor.

In some embodiments, the fluorine-containing p-type semiconductor may be a light absorbing compound including an electron donating moiety and an electron accepting moiety, and the electron donating moiety may include a fluorine.

In some embodiments, the fluorine-containing p-type semiconductor may be a light absorbing compound represented by any one of Chemical Formulas 1 to 4.

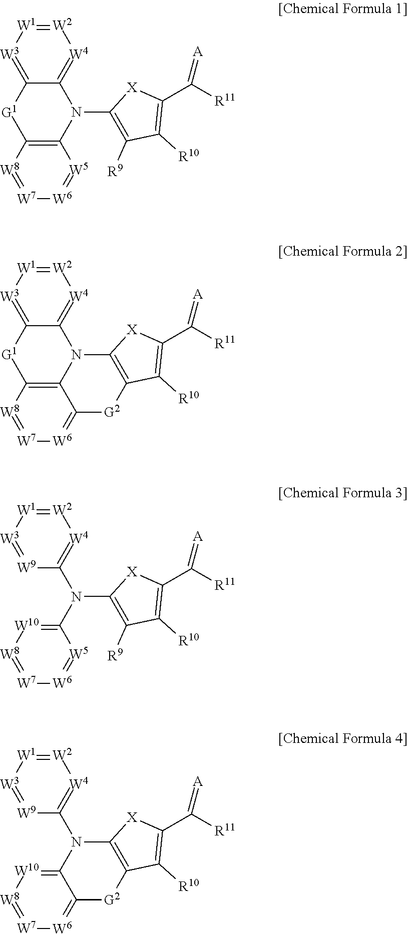

In Chemical Formulas 1 to 4,
X is O, S, Se, Te, SO, SO₂, CR^{a}R^{b}, SiR^{c}R^{d}, or GeR^{e}R^{f},
W¹ to W¹⁰ are each independently N or CR¹⁰⁰, and at least one of W¹ to W⁸ is CR¹⁰⁰,
G¹ and G² are each independently a single bond, O, S, Se, Te, CR^{g}R^{h}, SiRⁱR^{j}, or GeR^{k}R^{l},
A is an electron accepting moiety,
R⁹ to R¹¹, R¹⁰⁰, and R^{a} to R^{l} are each independently hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
at least one of R¹⁰⁰ and R^{g} to R^{l} is a fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof, and
R⁹ to R¹¹, R¹⁰⁰, and R^{a} to R^{l} are each independently present or an adjacent two of R⁹ to R¹¹, R¹⁰⁰ and R^{a} to R^{l} are linked to each other to form a ring.

In some embodiments, the fluorine-containing p-type semiconductor may be a light absorbing compound represented by any one of Chemical Formulas 1-1 to 4-1.

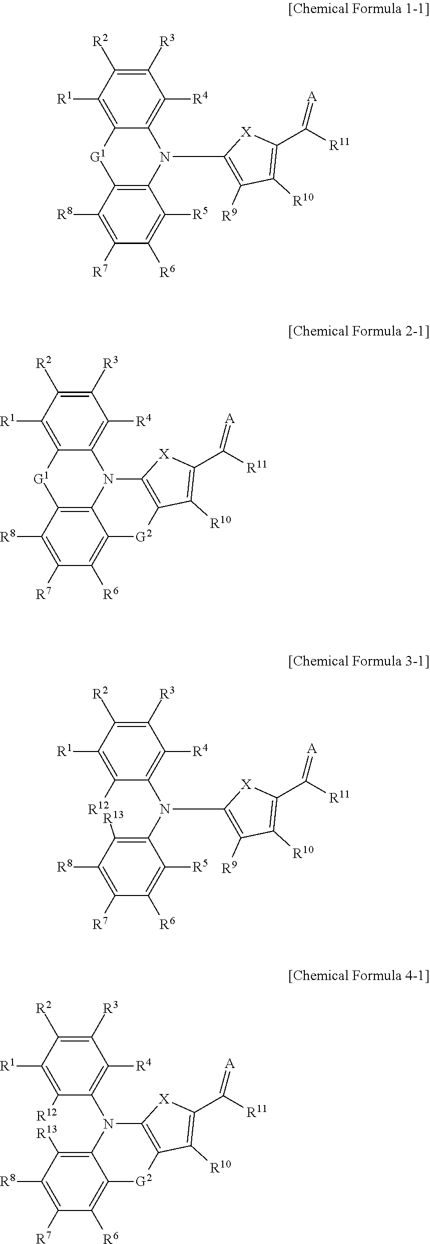

In Chemical Formulas 1-1 to 4-1,
X is O, S, Se, Te, SO, SO₂, CR^{a}R^{b}, SiR^{c}R^{a}, or GeR^{e}R^{f},
G¹ and G² are each independently a single bond, O, S, Se, Te, CR^{g}R^{h}, SiRⁱR^{j}, or GeR^{k}R^{l},
A is a cyclic group including C═Z¹, a halogen, a C1 to C30 haloalkyl group, a cyano group, a dicyanovinyl group, or any combination thereof, wherein Z¹ is O, S, Se, Te, or CR^{m}Rⁿ, wherein R^{m} and Rⁿ are each independently hydrogen, deuterium, a substituted or unsubstituted C1 to C20 alkyl group, a carbonyl group, a cyano group, a dicyanovinyl group, or any combination thereof, and R^{m} and Rⁿ are each independently present or are linked to each other to form a ring,
R¹ to R¹³ and R^{a} to R^{l} are each independently hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
R¹ to R¹³ and R^{a} to R^{l} are each independently present or an adjacent two of R¹ to R¹³ and R^{a} to R^{l} are linked to each other to form a ring,
at least one of R¹ to R⁸ and R^{g} to R^{l} in Chemical Formula 1-1 or 2-1 includes a fluorine, and
at least one of R¹ to R⁸, R¹², R¹³, and R^{g} to R^{l} in Chemical Formula 3-1 or 4-1 includes a fluorine.

In some embodiments, in Chemical Formula 1-1, Chemical Formula 2-1, or both Chemical Formula 1-1 and Chemical Formula 2-1, at least one of R¹, R², R³, R⁴, R⁵, R⁶, R⁷, R⁸, R^{g}, R^{h}, Rⁱ, R^{j}, R^{k}, and R¹ may be fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof. In some embodiments, in Chemical Formula 3-1, Chemical Formula 4-1, or both Chemical Formula 3-1 and Chemical Formula 4-1, at least one of R¹, R², R³, R⁴, R⁵, R⁶, R⁷, R⁸, R⁹, R¹⁰, R¹¹, R¹², R¹³, R^{g} , R^{h}, Rⁱ, R^{j}, R^{k}, and R^{l} may be fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof.

In some embodiments, at least one of R², R³, R⁶, and R⁷ of Chemical Formulas 1-1 to 4-1 may be a fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof.

In some embodiments, A of Chemical Formulas 1 to 4 may be a cyclic group including C═Z¹, a halogen, a C1 to C30 haloalkyl group, a cyano group, a dicyanovinyl group, or any combination thereof. Z¹ may be O, S, Se, Te, or CR^{m}Rⁿ, wherein R^{m} and Rⁿ may each independently be hydrogen, deuterium, a substituted or unsubstituted C1 to C20 alkyl group, a carbonyl group, a cyano group, a dicyanovinyl group, or any combination thereof, and R^{m} and Rⁿ may each independently present or may be linked to each other to form a ring,

In some embodiments, A may be a cyclic group represented by any one of Chemical Formulas AA to AE.

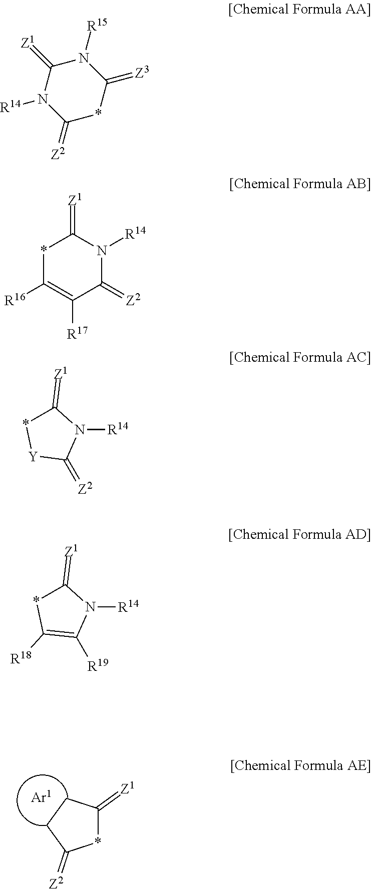

In Chemical Formulas AA to AE,
Z¹ to Z³ are each independently O, S, Se, Te, or CR^{m}Rⁿ, wherein R^{m} and Rⁿ are each independently hydrogen, deuterium, a substituted or unsubstituted C1 to C20 alkyl group, a carbonyl group, a cyano group, a dicyanovinyl group, or any combination thereof, and R^{m} and Rⁿ are each independently present or are linked to each other to form a ring,
Y is O, S, Se, or Te,
Ar¹ is a substituted or unsubstituted C6 to C30 arylene group, a substituted or unsubstituted C3 to C30 cycloalkylene group, a substituted or unsubstituted C3 to C30 cycloalkenylene group, a substituted or unsubstituted C2 to C30 heterocyclic group, or a fused ring thereof,
R¹⁴ to R¹⁹ are each independently hydrogen, deuterium, a substituted or unsubstituted C1 to C20 alkyl group, a substituted or unsubstituted C2 to C30 alkenyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, or any combination thereof,
R¹⁴ to R¹⁹ are each independently present or an adjacent two of R¹⁴ to R¹⁹ are linked to each other to form a ring, and
* is a linking point with any one of Chemical Formulas 1 to 4.

In some embodiments, a sublimation temperature of the fluorine-containing p-type semiconductor and a sublimation temperature of the non-fullerene n-type semiconductor each may be about 100° C. to about 400° C. A difference between the sublimation temperature of the fluorine-containing p-type semiconductor and the sublimation temperature of the non-fullerene n-type semiconductor may be greater than or equal to about 0° C. and less than about 150° C. A sublimation temperature may be a temperature at which a weight loss of 10% relative to an initial weight occurs during thermogravimetric analysis at 10 Pa or less.

In some embodiments, the light emitting layer may include an organic light emitting material. A difference between the sublimation temperature of the fluorine-containing p-type semiconductor, the sublimation temperature of the non-fullerene n-type semiconductor, and a sublimation temperature of the organic light emitting material may be greater than or equal to about 0° C. and less than about 150° C.

In some embodiments, a difference between a HOMO energy level of the fluorine-containing p-type semiconductor and a HOMO energy level of the first common auxiliary layer may be greater than or equal to about 0 eV and less than about 1.0 eV.

In some embodiments, a non-fullerene n-type semiconductor may be a transparent semiconductor that does not substantially absorb light in a visible wavelength spectrum.

In some embodiments, a photosensitive layer may consist of the fluorine-containing p-type semiconductor and the non-fullerene n-type semiconductor.

In some embodiments, the photosensitive layer may include a first photosensitive layer and a second photosensitive layer. The first photosensitive layer may consist of the fluorine-containing p-type semiconductor. The second photosensitive layer may consist of the non-fullerene n-type semiconductor. The first photosensitive layer may be closer to the first common auxiliary layer than the second photosensitive layer.

In some embodiments, the light emitting element may include a first light emitting element, a second light emitting element, and a third light emitting element. The first light emitting element, the second light emitting element, and the third light emitting element may be configured to emit light of different wavelength spectra from each other. The photosensor may be configured to absorb reflected emitted light and convert absorbed reflected emitted light into an electrical signal. The reflected emitted light may be light emitted from at least one of the first light emitting element, the second light emitting element, or the third light emitting element and then reflected by a recognition target to the photosensor.

In some embodiments, the sensor-embedded display panel may further include a common electrode configured to apply a common voltage to the light emitting element and the photosensor.

In some embodiments, the light emitting element and the photosensor may further include respective portions of a second common auxiliary layer. The second common auxiliary layer may be between the common electrode and the light emitting layer and between the common electrode and the photosensitive layer. The second common auxiliary layer may be continuous along the in-plane direction of the substrate and on the light emitting layer and the photosensitive layer.

In some embodiments, the sensor-embedded display panel may further include a common electrode configured to apply a common voltage to the light emitting element and the photosensor.

In some embodiments, the light emitting element and the photosensor may further include respective portions of a second common auxiliary layer. The second common auxiliary layer may be between the common electrode and the light emitting layer and between the common electrode and the photosensitive layer. The second common auxiliary layer may be continuous along the in-plane direction of the substrate and on the light emitting layer and the photosensitive layer.

In some embodiments, a difference between a LUMO energy level of the non-fullerene n-type semiconductor and a LUMO energy level of the second common auxiliary layer may be greater than or equal to about 0 eV and less than about 1.0 eV.

In some embodiments, the sensor-embedded display panel may include a display area and a non-display area excluding the display area. The display area may be configured to display a color. The light emitting element may be in the display area and the photosensor is in the non-display area.

In some embodiments, the light emitting element may include a first light emitting element configured to emit light of a red wavelength spectrum, a second light emitting element configured to emit light of a green wavelength spectrum, and a third light emitting element configured to emit light of a blue emission spectrum. The display area may include a plurality of first subpixels configured to display red, a plurality of second subpixels configured to display green, and a plurality of third subpixels configured to display blue. The plurality of first subpixels may include the first light emitting element. The plurality of second subpixels may include the second light emitting element. The plurality of third subpixels may include the third light emitting element. The photosensor may be between two of the first subpixel, the second subpixel, and the third subpixel.

According to some example embodiments, a sensor-embedded display panel includes a light emitting element including a light emitting layer configured to emit light of a desired wavelength spectrum, and a photosensor including a photosensitive layer configured to absorb light belonging to a wavelength spectrum of light emitted from the light emitting layer. The photosensitive layer may include a light absorbing compound represented by any one of Chemical Formulas 1 to 4.

In some embodiments, the light absorbing compound may be represented by any one of Chemical Formulas 1-1 to 4-1.

In some embodiments, the light emitting layer and the photosensitive layer may be arranged in parallel along the in-plane direction of the substrate. The photosensor may be configured to absorb reflected emitted light and convert absorbed reflected emitted light into an electrical signal. The reflected emitted light may be light emitted from at least one of the first light emitting element, the second light emitting element, or the third light emitting element and then reflected by a recognition target to the photosensor.

In some embodiments, a peak absorption wavelength of the light absorbing compound may be in a range of about 500 nm to about 600 nm, and the photosensitive layer may further include a transparent semiconductor that does not substantially absorb light of a visible wavelength spectrum.

In some embodiments, sensor-embedded display panel may further include a first common auxiliary layer between the substrate and the light emitting layer and between the substrate and the photosensitive layer, a common electrode configured to apply a common voltage to the light emitting element and the photosensor, and a second common auxiliary layer between the common electrode and the light emitting layer and between the common electrode and the photosensitive layer. The first common auxiliary layer may be continuous under each of the and the light emitting layer and the photosensitive layer. The second common auxiliary layer may be continuous on the light emitting layer and the photosensitive layer.

In some embodiments, a difference between HOMO energy levels of the photosensitive layer and the first common auxiliary layer may be greater than or equal to about 0 eV and less than about 1.0 eV, and a difference between LUMO energy levels of the photosensitive layer and the second common auxiliary layer may be greater than or equal to 0 eV and less than about 1.0 eV.

According to some example embodiments, an electronic device including the sensor-embedded display panel may be provided.

A sensor with improved optical and electrical performance and processibility may be integrated into the display panel, thereby realizing a high-performance sensor while improving design and usability.

### BRIEF DESCRIPTION OF THE DRAWINGS

FIG. 1 is a plan view showing an example of a sensor-embedded display panel according to some example embodiments,

FIG. 2A is a cross-sectional view illustrating an example of a sensor-embedded display panel according to some example embodiments,

FIG. 2B is an example structure of a photosensitive layer in a sensor-embedded display according to some example embodiments;

FIGS. 3A, 3B, and 3C are schematic views illustrating examples of a smart phone, a table device, and a computer as an electronic device according to some example embodiments, and

FIG. 4 is a schematic view illustrating an example of a configuration diagram of an electronic device according to some example embodiments.

### DETAILED DESCRIPTION

As used herein, expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments will be described in detail so that a person skilled in the art would understand the same. However, a structure that is actually applied may be implemented in various different forms and is not limited to the embodiments described herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

Hereinafter, the terms “lower” and “upper” are used for better understanding and ease of description, but do not limit the location relationship.

As used herein, when a definition is not otherwise provided, “substituted” refers to replacement of hydrogen of a compound or a group by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or any combination thereof.

As used herein, when a definition is not otherwise provided, “hetero” refers to one including 1 to 4 heteroatoms selected from N, O, S, Se, Te, Si, and P.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, a sensor-embedded display panel according to some example embodiments is described.

The sensor-embedded display panel according to some example embodiments may be a display panel capable of performing a display function and a recognition function (e.g., biometric recognition function), and may be an in-cell type display panel in which a sensor performing a recognition function (e.g., biometric recognition function) is embedded in the display panel.

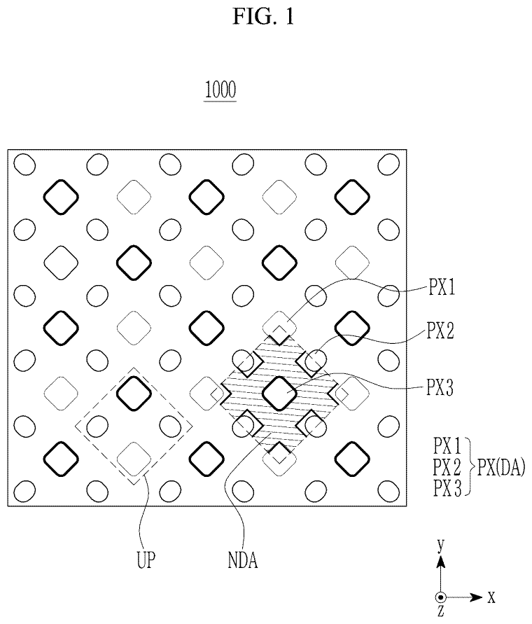

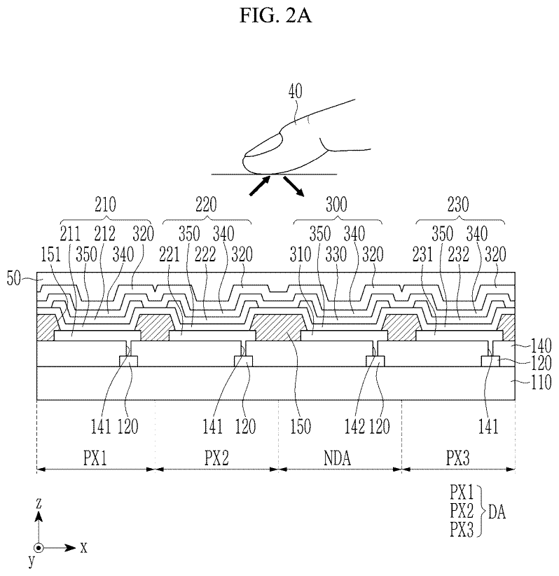

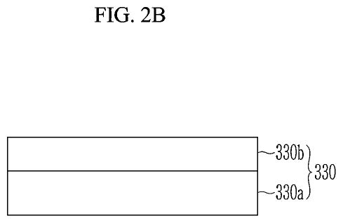

FIG. 1 is a plan view showing an example of a sensor-embedded display panel according to some example embodiments and FIG. 2A is a cross-sectional view illustrating an example of a sensor-embedded display panel according to some example embodiments.

Referring to FIGS. 1 and 2A, a sensor-embedded display panel 1000 according to some example embodiments includes a plurality of subpixels PXs configured to displaying different colors each other. The plurality of subpixels PXs may be configured to display at least three primary colors, for example, a first subpixel PX1, a second subpixel PX2, and a third subpixel PX3 configured to display different first color, second color, and third color selected from red, green, and blue. For example, the first color, the second color, and the third color may be red, green, and blue, respectively. The first subpixel PX1 may be a red subpixel configured to display red, the second subpixel PX2 may be a green subpixel configured to display green, and the third subpixel PX3 may be a blue subpixel configured to display blue. However, the present disclosure is not limited thereto, and an auxiliary subpixel (not shown) such as a white subpixel may be further included.

The plurality of subpixels PXs including the first subpixel PX1, the second subpixel PX2, and the third subpixel PX3 may constitute one unit pixel UP to be arranged repeatedly along the row and/or column. In FIG. 1, a structure including one first subpixel PX1, two second subpixels PX2, and one third subpixel PX3 in the unit pixel UP is illustrated, but the present disclosure is not limited thereto. At least one first subpixel PX1, at least one second subpixel PX2, and at least one third subpixel PX3 may be included in the unit pixel UP. In the drawing, as an example, an arrangement of a Pentile type is illustrated, but the present disclosure is not limited thereto. The subpixels PXs may be arranged variously. An area occupied by the plurality of subpixels PXs and displaying colors by the plurality of subpixels PXs may be a display area DA configured to display an image.

Each of the first subpixel PX1, the second subpixel PX2, and the third subpixel PX3 may include a light emitting element. As an example, the first subpixel PX1 may include a first light emitting element 210 configured to emit light of a wavelength spectrum of a first color, the second subpixel PX2 may include a second light emitting element 220 configured to emit light of a wavelength spectrum of a second color, and the third subpixel PX3 may include a third light emitting element 230 configured to emit light of a wavelength spectrum of a third color. However, the present disclosure is not limited thereto, and at least one of the first subpixel PX1, the second subpixel PX2, or the third subpixel PX3 may include a light emitting element configured to emit light of a combination of a first color, a second color, and a third color, that is, light in a white wavelength spectrum, and may be configured to display a first color, a second color, or a third color through a color filter (not shown).

The sensor-embedded display panel 1000 according to some example embodiments includes a photosensor 300. The photosensor 300 may be disposed in a non-display area NDA. The non-display area NDA may be an area other than the display area DA, in which the first subpixel PX1, the second subpixel PX2, the third subpixel PX3, and optionally auxiliary subpixels are not disposed. The photosensor 300 may be between at least two of the first subpixel PX1, the second subpixel PX2, and the third subpixel PX3, and may be in parallel with the first, second, and third light emitting elements 210, 220, and 230 in the display area DA.

The photosensor 300 may be an optical type recognition sensor (e.g., a biometric sensor), and may be configured to absorb light emitted from at least one of the first, second or third light emitting elements 210, 220, and 230 in the display area DA and then reflected by a recognition target 40 such as a living body, a tool, or an object to convert the absorbed light into an electrical signal. Herein, the living body may be a finger, a fingerprint, a palm, an iris, a face, and/or a wrist, but is not limited thereto. The photosensor 300 may be, for example, a fingerprint sensor, an illumination sensor, an iris sensor, a distance sensor, a blood vessel distribution sensor, and/or a heart rate sensor, but is not limited thereto.

The photosensor 300 may be in the same plane as the first, second, and third light emitting elements 210, 220, and 230 on the substrate 110, and may be embedded in the display panel 1000.

Referring to FIG. 2A, the sensor-embedded display panel 1000 includes a substrate 110; a thin film transistor 120 on the substrate 110; an insulation layer 140 on the thin film transistor 120; a pixel definition layer 150 on the insulation layer 140; and first, second, or third light emitting elements 210, 220, and 230 and the photosensor 300 in a space partitioned by the pixel definition layer 150.

The substrate 110 may be a light-transmitting substrate, for example, a glass substrate or a polymer substrate. The polymer substrate may include, for example, polycarbonate, polymethylmethacrylate, polyethyleneterephthalate, polyethylenenaphthalate, polyimide, polyamide, polyamideimide, polyethersulfone, polyorganosiloxane, styrene-ethylene-butylene-styrene, polyurethane, polyacrylate, polyolefin, or any combination thereof, but is not limited thereto.

A plurality of thin film transistors 120 are formed on the substrate 110. One or more thin film transistor 120 may be included in each subpixel PX, and may include, for example, at least one switching thin film transistor and/or at least one driving thin film transistor. The substrate 110 on which the thin film transistor 120 is formed may be referred to as a thin film transistor substrate (TFT substrate) or a thin film transistor backplane (TFT backplane).

The insulation layer 140 may cover the substrate 110 and the thin film transistor 120 and may be formed on the whole surface of the substrate 110. The insulation layer 140 may be a planarization layer or a passivation layer, and may include an organic insulating material, an inorganic insulating material, an organic-inorganic insulating material, or any combination thereof. The insulation layer 140 may include an organic, inorganic, or organic-inorganic insulating material, in some example embodiments, an inorganic insulating material such as silicon oxide, silicon nitride, silicon oxynitride, aluminum oxide, aluminum nitride, or aluminum oxynitride; an organic insulating material such as polyimide, polyamide, polyamideimide, or polyacrylate; or an organic-inorganic insulating material such as polyorganosiloxane or polyorganosilazane. The insulation layer 140 may have a plurality of contact holes 141 for connecting the first, second, and third light emitting elements 210, 220, and 230 and the thin film transistor 120 and a plurality of contact holes 142 for electrically connecting the photosensor 300 and the thin film transistor 120.

The pixel definition layer 150 may also be formed on the whole surface of the substrate 110 and may be between adjacent subpixels PXs to partition each subpixel PX. The pixel definition layer 150 be an insulation layer that may include an organic, inorganic, or organic-inorganic insulating material, in some example embodiments, an inorganic insulating material such as silicon oxide, silicon nitride, or silicon oxynitride; an organic insulating material such as polyimide; or an organic-inorganic insulating material such as polyorganosiloxane or polyorganosilazane. The pixel definition layer 150 may have a plurality of openings 151 in each subpixel PX, and in each opening 151, any one of first, second, and third light emitting elements 210, 220, and 230 and the photosensors 300 may be disposed.

The first, second and third light emitting elements 210, 220, and 230 are formed on the substrate 110 (or thin film transistor substrate), and are repeatedly arranged along the in-plane direction (e.g., xy direction) of the substrate 110. As described above, the first, second, and third light emitting elements 210, 220, and 230 may be included in the first subpixel PX1, the second subpixel PX2, and the third subpixel PX3, respectively. The first, second, and third light emitting elements 210, 220, and 230 may be electrically connected to separate thin film transistors 120 and may be driven independently.

The first, second, and third light emitting elements 210, 220, and 230 may be configured to each independently emit light of one selected from a red wavelength spectrum, a green wavelength spectrum, a blue wavelength spectrum, and any combination thereof. For example, the first light emitting element 210 may be configured to emit light of a red wavelength spectrum, the second light emitting element 220 may be configured to emit light of a green wavelength spectrum, and the third light emitting element 230 may be configured to emit light of a blue wavelength spectrum. Herein, the red wavelength spectrum, the green wavelength spectrum, and the blue wavelength spectrum may have a maximum emission wavelength (λ_{peak,L}) in a wavelength region of greater than about 600 nm and less than about 750 nm, about 500 nm to about 600 nm, and greater than or equal to about 400 nm and less than about 500 nm, respectively.

The first, second, and third light emitting elements 210, 220, and 230 may be, for example, light emitting diodes, for example organic light emitting diodes (OLEDs) including an organic light emitting material.

The photosensor 300 may be formed on the substrate 110 (or the thin film transistor substrate), and may be randomly or regularly arranged along the in-plane direction (e.g., xy direction) of the substrate 110. As described above, the photosensor 300 may be in the non-display area NDA, and may be connected to a separate thin film transistor 120 to be independently driven. The photosensor 300 may be configured to absorb light belonging to a wavelength spectrum of the light emitted from at least one of the first, second, and third light emitting elements 210, 220, and 230 and then convert the absorbed light into an electrical signal. For example, the photosensor 300 may be configured to absorb light of a red wavelength spectrum and a green wavelength spectrum, a blue wavelength spectrum, and any combination thereof, and then convert the absorbed light into an electrical signal and for example, light of a green wavelength spectrum may be absorbed and converted into an electrical signal. The photosensor 300 may be, for example, a photoelectric conversion diode, for example an organic photoelectric conversion diode including an organic photoelectric conversion material.

Each of the first, second, and third light emitting elements 210, 220, and 230 and the photosensor 300 may include a pixel electrode 211, 221, 231, and 310; a common electrode 320 facing the pixel electrodes 211, 221, 231, and 310 and to which a common voltage is applied; and light emitting layers 212, 222, and 232 or a photosensitive layer 330, a first common auxiliary layer 350, and a second common auxiliary layer 340 between the pixel electrode 211, 221, 231, and 310 and the common electrode 320.

The first, second, and third light emitting elements 210, 220, and 230 and the photosensor 300 may be arranged in parallel along the in-plane direction (e.g., xy direction) of the substrate 110, and may share the common electrode 320, the first common auxiliary layer 350, and the second common auxiliary layer 340 which are formed on the whole surface of the substrate 110.

The common electrode 320 is continuously formed on the light emitting layers 212, 222, and 232 and the photosensitive layer 330, and is substantially formed on the whole surface of the substrate 110. The common electrode 320 may apply a common voltage to the first, second, and third light emitting elements 210, 220, and 230 and the photosensor 300.

The common electrode 320 may be a light-transmitting electrode configured to transmit light. The light-transmitting electrode may be a transparent electrode or a semi-transmissive electrode. The transparent electrode may have a light transmittance of greater than or equal to about 85%, greater than or equal to about 90%, or greater than or equal to about 95% and the semi-transmissive electrode may have a light transmittance of greater than or equal to about 30% and less than about 85%, about 40% to about 80%, or about 40% to about 75%. The transparent electrode and the semi-transmissive electrode may include, for example, at least one of an oxide conductor, a carbon conductor, or a metal thin film. The oxide conductors may include, for example, one or more of indium tin oxide (ITO), indium zinc oxide (IZO), zinc tin oxide (ZTO), aluminum tin oxide (ATO), and aluminum zinc oxide (AZO), the carbon conductor may include one or more selected from graphene and carbon nanostructures, and the metal thin film may be a very thin film including aluminum (Al), magnesium (Mg), silver (Ag), gold (Au), magnesium-silver (Mg—Ag), magnesium-aluminum (Mg—Al), an alloy thereof, or any combination thereof.

The first common auxiliary layer 350 may be between the light emitting layers 212, 222, and 232 and the photosensitive layer 330 and the substrate 110, and among them, between the light emitting layers 212, 222, and 232 and the photosensitive layer 330 and the pixel electrodes 211, 221, 231, and 310. The first common auxiliary layer 350 may be continuously formed under the light emitting layers 212, 222, and 232 and the photosensitive layer 330 and on the pixel electrodes 211, 221, 231, and 310, along the in-plane direction of the substrate.

The first common auxiliary layer 350 may be a charge auxiliary layer (e.g., hole auxiliary layer) that facilitates injection and/or movement of charge carriers (e.g., holes) from the pixel electrodes 211, 221, and 231 to the light emitting layers 212, 222, and 232. For example, the HOMO energy level of the first common auxiliary layer 350 may be between the HOMO energy level of the light emitting layers 212, 222, and 232 and the work function of the pixel electrodes 211, 221, and 231. The work function of the pixel electrodes 211, 221, and 231, the HOMO energy level of the first common auxiliary layer 350, and the HOMO energy level of the light emitting layers 212, 222, and 232 may become sequentially deep.

The first common auxiliary layer 350 may include an organic material, an inorganic material, an organic-inorganic material, or any combination thereof satisfying the HOMO energy level, for example a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris{2-naphthyl-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonic acid), PANI/PSS (polyaniline/poly(4-styrenesulfonate)), NPB (N,N′-di(naphthalene-l-yl)-N,N′-diphenylbenzidine), polyetherketone including triphenylamine (TPAPEK), 4-isopropyl-4′-methyldiphenyliodonium[tetrakis(pentafluorophenyl)borate], HAT-CN (dipyrazino[2,3-f: 2′,3′-h] quinoxaline-2,3,6,7,10,11-hexacarbonitrile), a carbazole-based derivative such as N-phenylcarbazole, polyvinylcarbazole, and the like, a fluorene-based derivative, TPD (N,N′-bis(3-methylphenyl)-N,N′-diphenyl-[1,1-biphenyl]-4,4′-diamine), a triphenylamine-based derivative such as TCTA (4,4′,4″-tris(N-carbazolyl)triphenylamine), NPB (N,N′-di(naphthalene-l-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or any combination thereof, but is not limited thereto. The first common auxiliary layer 350 may be one layer or two or more layers.

The second common auxiliary layer 340 may be between the light emitting layers 212, 222, and 232 and the common electrode 320 and between the photosensitive layer 330 and the common electrode 320, and may be continuously formed on the light emitting layers 212, 222, and 232 and the photosensitive layer 330 and under the common electrode 320, along the in-plane direction of the substrate.

The second common auxiliary layer 340 may be a charge auxiliary layer (e.g., an electron auxiliary layer) that facilitates injection and/or movement of charges (e.g., electrons) from the common electrode 320 to the light emitting layers 212, 222, and 232. For example, an LUMO energy level of the second common auxiliary layer 340 may be between an LUMO energy level of the light emitting layers 212, 222, and 232 and a work function of the common electrode 320. The work function of the common electrode 320, the LUMO energy level of the first common auxiliary layer 340, and the LUMO energy level of the light emitting layers 212, 222, and 232 may become shallow in sequence.

The second common auxiliary layer 340 may include an organic material, an inorganic material, an organic-inorganic material, or any combination thereof satisfying the LUMO energy level, for example a halogenated metal such as LiF, NaCl, CsF, RbCl, and Rbl; a lanthanides metal such as Yb; a metal oxide such as Li₂O or BaO; Liq (lithium quinolate), Alq3 (tris(8-hydroxyquinolinato)aluminum), 1,3,5-tri[(3-pyridyl)-phen-3-yl]benzene, 2,4,6-tris (3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq₂ (berylliumbis(benzoquinolin-10-olate), ADN (9,10-di(naphthalene-2-yl)anthracene), BmPyPhB (1,3-bis[3,5-di(pyridin-3-yl)phenyl]benzene), or any combination thereof, but is not limited thereto. The second common auxiliary layer 340 may be one layer or two or more layers.

Each of the first, second, and third light emitting elements 210, 220, and 230 and the photosensor 300 includes pixel electrodes 211, 221, 231, and 310 facing the common electrode 320. One of the pixel electrodes 211, 221, 231, and 310 or the common electrode 320 is an anode, and the other is a cathode. For example, the pixel electrodes 211, 221, 231, and 310 may be an anode, and the common electrode 320 may be a cathode. The pixel electrodes 211, 221, 231, and 310 are separated for each subpixel PX, and are electrically connected to each separate thin film transistor 120 to be independently driven.

The pixel electrodes 211, 221, 231, and 310 may be a light-transmitting electrode (a transparent electrode or a semi-transmissive electrode) or a reflective electrode. The light-transmitting electrode is the same as described above.

The reflective electrode may include a reflective layer having a light transmittance of less than or equal to about 5% and/or a reflectance of greater than or equal to about 80%, and the reflective layer may include an optically opaque material. The optically opaque material may include a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto. The reflective electrode may be formed of a reflective layer or may have a stacked structure of a reflective layer/transmissive layer or a transmissive layer/reflective layer/transmissive layer, and the reflective layer may be one layer or two or more layers.

For example, when the pixel electrodes 211, 221, 231, and 310 are reflective electrodes and the common electrode 320 is a light-transmitting electrode, the sensor-embedded display panel 1000 may be a top emission type display panel configured to emit light toward the opposite side of the substrate 110. For example, when the pixel electrodes 211, 221, 231, and 310 and the common electrode 320 are light-transmitting electrodes, respectively, the sensor-embedded display panel 1000 may be a both side emission type display panel configured to emit light toward both the substrate 110 and the opposite side of the substrate 110.

For example, the pixel electrodes 211, 221, 231, and 310 may be reflective electrodes and the common electrode 320 may be a semi-transmissive electrode. In this case, the sensor-embedded display panel 1000 may have a microcavity structure. In the microcavity structure, reflection may occur repeatedly between the reflective electrode and the semi-transmissive electrode separated by a desired and/or alternatively predetermined optical length (e.g., a distance between the semi-transmissive electrode and the reflective electrode) and light of a desired and/or alternatively predetermined wavelength spectrum may be enhanced to improve optical properties.

For example, among the light emitted from the light emitting layers 212, 222, and 232 of the first, second, and third light emitting elements 210, 220, and 230, light of a desired and/or alternatively predetermined wavelength spectrum may be repeatedly reflected between the semi-transmissive electrode and the reflective electrode and then may be modified. Among the modified light, light of a wavelength spectrum corresponding to a resonance wavelength of a microcavity may be enhanced to exhibit amplified light emission characteristics in a narrow wavelength region. Accordingly, the sensor-embedded display panel 1000 may express colors with high color purity.

For example, among the light incident on the photosensor 300, light of a desired and/or alternatively predetermined wavelength spectrum may be repeatedly reflected between the semi-transmissive electrode and the reflective electrode to be modified. Among the modified light, light having a wavelength spectrum corresponding to the resonance wavelength of a microcavity may be enhanced to exhibit photoelectric conversion characteristics amplified in a narrow wavelength region. Accordingly, the photosensor 300 may exhibit high photoelectric conversion characteristics in a narrow wavelength region.

Each of the first, second, and third light emitting elements 210, 220, and 230 includes light emitting layers 212, 222, and 232 between the pixel electrodes 211, 221, and 231 and the common electrode 320. Each of the light emitting layer 212 included in the first light emitting element 210, the light emitting layer 222 included in the second light emitting element 220, and the light emitting layer 232 included in the third light emitting element 230 may be configured to emit light in the same or different wavelength spectra and may be configured to emit light in, for example a red wavelength spectrum, a green wavelength spectrum, a blue wavelength spectrum, or any combination thereof.

For example, when the first light emitting element 210, the second light emitting element 220, and the third light emitting element 230 are a red light emitting elements, a green light emitting element, and a blue light emitting element, respectively, the light emitting layer 212 may be a red light emitting layer configured to emit light in a red wavelength spectrum, the light emitting layer 222 included in the second light emitting element 220 may be a green light emitting layer configured to emit light in a green wavelength spectrum, and the light emitting layer 232 included in the third light emitting element 230 may be a blue light emitting layer configured to emit light in a blue wavelength spectrum. Herein, the red wavelength spectrum, the green wavelength spectrum, and the blue wavelength spectrum may have a peak absorption wavelength of greater than about 600 nm and less than about 750 nm, about 500 nm to about 600 nm, and greater than or equal to about 380 nm and less than about 500 nm, respectively.

For example, when at least one of the first light emitting element 210, the second light emitting element 220, or the third light emitting element 230 is a white light emitting element, the light emitting layer of the white light emitting element may be configured to emit light of a full visible light wavelength spectrum, for example, light in a wavelength spectrum of greater than or equal to about 380 nm and less than about 750 nm, about 400 nm to about 700 nm, or about 420 nm to about 700 nm.

The light emitting layers 212, 222, and 232 may include at least one host material and a fluorescent or phosphorescent dopant, and at least one of the at least one host material and the fluorescent or phosphorescent dopant may be an organic light emitting material. The organic light emitting material may include, for example, a low molecular organic light emitting material, for example, a vapor depositable organic light emitting material.

The organic light emitting material included in the light emitting layers 212, 222, 232 is not particularly limited as long as it is an electroluminescent material capable of emitting light of a desired and/or alternatively predetermined wavelength spectrum, and may be, for example, perylene; rubrene; 4-(dicyanomethylene)-2-methyl-6-[p-(dimethylamino)styryl]-4H-pyran; coumarin or a derivative thereof; carbazole or a derivative thereof; TPBi (2,2′,2″-(1,3,5-benzinetriyl)-tris(1-phenyl-1-H-benzimidazole); TBADN (2-t-butyl-9,10-di(naphth-2-yl)anthracene); AND (9,10-di(naphthalene-2-yl)anthracene); CBP (4,4′-bis(N-carbazolyl)-1,1′-biphenyl); TCTA (4,4′,4″-tris(carbazol-9-yl)-triphenylamine); TPBi (1,3,5-tris(N-phenylbenzimidazole-2-yl)benzene); TBADN (3-tert-butyl-9,10-di(naphth-2-yl)anthracene); DSA (distyrylarylene); CDBP (4,4′-bis(9-carbazolyl)-2,2′-dimethyl-biphenyl); MADN (2-Methyl-9,10-bis(naphthalen-2-yl)anthracene); TCP (1,3,5-tris(carbazol-9-yl)benzene); Alq3 (tris(8-hydroxyquinolino)lithium); an organometallic compound including Pt, Os, Ti, Zr, Hf, Eu, Tb, Tm, Rh, Ru, Re, Be, Mg, Al, Ca, Mn, Co, Cu, Zn, Ga, Ge, Pd, Ag and/or Au, a derivative thereof, or any combination thereof, but is not limited thereto.

The organic light emitting material included in the light emitting layers 212, 222, and 232 may be a depositable organic light emitting material that may be vaporized (sublimated) at a desired and/or alternatively predetermined temperature to be deposited, and may have a desired and/or alternatively predetermined sublimation temperature Ts. Here, the sublimation temperature may be a temperature at which a weight loss of 10% relative to the initial weight occurs during thermogravimetric analysis TGA at a low pressure of about 10 Pa or less, and may be a deposition temperature during the process or a set temperature of a deposition chamber used in the process. The sublimation temperature Ts of the organic light emitting material included in the light emitting layers 212, 222, and 232 may be less than or equal to about 350° C., and within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., about 150° C. to about 260° C., or about 150° C. to about 250° C. When the organic light emitting material has a sublimation temperature within the above range, it may be effectively deposited without substantial decomposition and/or loss of the organic light emitting material.

The photosensor 300 includes a photosensitive layer 330 between the pixel electrode 310 and the common electrode 320. The photosensitive layer 330 is in parallel with the light emitting layers 212, 222, and 232 of the first, second, and third light emitting elements 210, 220, and 230 along the in-plane direction (e.g., xy direction) of the substrate 110. The photosensitive layer 330 and the light emitting layers 212, 222, and 232 may be on the same plane.

The photosensitive layer 330 may be a photoelectric conversion layer configured to absorb light of a desired and/or alternatively predetermined wavelength spectrum and convert the absorbed light into an electrical signal, and may be configured to absorb the light emitted from at least one of the aforementioned first, second, and third light emitting elements 210, 220, and 230 and then reflected by the recognition target 40 and may be configured to convert the absorbed light into an electrical signal. The photosensitive layer 330 may be configured to absorb light of, for example, a red wavelength spectrum, a green wavelength spectrum, a blue wavelength spectrum, or any combination thereof.

For example, the photosensitive layer 330 may be configured to selectively absorb light of a green wavelength spectrum having a peak absorption wavelength Apeak,A in a wavelength region of about 500 nm to about 600 nm, and may be configured to absorb light that is emitted from the green light emitting element among the first, second, and third light emitting elements 210, 220, and 230 and then reflected by the recognition target 40. The peak absorption wavelength λ_{peak,A} of the photosensitive layer 130 may belong to about 510 nm to about 580 nm, about 520 nm to about 570 nm, about 520 nm to about 560 nm, or about 520 nm to about 550 nm within the above range.

The photosensitive layer 330 may include a p-type semiconductor and/or an n-type semiconductor configured to absorb light of the wavelength spectrum and photoelectric convert the absorbed light. The p-type semiconductor and the n-type semiconductor may form a pn junction, generate excitons by receiving light from the outside, and then separate the generated excitons into holes and electrons. As depicted in FIG. 2B, an example structure of the photosensitive layer 330 layer may include a first photosensitive layer 330a and a second photosensitive layer 330b on top of the first photosensitive layer 330a, where the first photosensitive layer 330a may be closer to the first common auxiliary layer 350 and the second photosensitive layer 330b may be closer to the second common auxiliary layer 340. The first photosensitive layer 330a may include (or consist of) the p-type semiconductor of the photosensitive layer 330 and the second photosensitive layer 330b may include (or consist of) the n-type semiconductor of the photosensitive layer 330. While FIG. 2B illustrates an example structure of the photosensitive layer 330, example embodiments are not limited thereto and the photosensitive layer 330 in other example embodiments may have a different structure than a bi-layer structure. For example, the photosensitive layer 330 alternatively may have a bulk heterojunction structure (not shown) in which the p-type semiconductor of the photosensitive layer 330 and the n-type semiconductor of the photosensitive layer 330 are mixed together in a same layer.

At least one of the p-type semiconductor or the n-type semiconductor may be a light absorbing material configured to absorb light of the aforementioned wavelength spectrum, and for example, may be an organic light absorbing material. Each of the p-type semiconductor and the n-type semiconductor may be a vapor-depositable material.

For example, the p-type semiconductor may be an organic light absorbing material and may be a depositable low molecular weight organic semiconductor material. The p-type semiconductor may have, for example, a D-A structure or a D-L-A structure (L is a linking group) including an electron donating moiety (D) and an electron accepting moiety (A).

As an example, the p-type semiconductor may be a fluorine-containing light absorbing compound including fluorine (F) in at least one of an electron donating moiety (D), an electron accepting moiety (A), and a linking group (L). For example, it may be a fluorine-containing light absorbing compound including at least one fluorine in the electron donating moiety (D). As such, by including the light absorbing compound of the D-A structure (or D-L-A structure) including fluorine in the photosensitive layer 330 as described above, light absorption characteristics and thus the photoelectric conversion characteristics may be improved, and at the same time the sublimation temperature (the temperature at which deposition is possible) may be lowered to improve processability, compared with the light absorbing compound of the D-A structure (or D-L-A structure) not including fluorine.

In general, the absorption characteristics of a compound and the sublimation temperature Ts of the compound tend to be proportional. Thus, when the molecular is designed to increase absorption characteristics of the compound, the sublimation temperature Ts of the compound may also increase, so that deposition at a higher temperature may be required. However, the light absorbing compound of the D-A structure (or D-L-A structure) including fluorine as described above may effectively form molecular stacking and may be deposited as a high-density thin film at a relatively low temperature by effective intramolecular and/or intermolecular interactions. In addition, since the light absorbing compound may be deposited at such a relatively low temperature, it may have high molecular stability by effectively reducing or preventing chemical bonds between moieties from being broken or damaged in the light absorbing compound of the D-A structure (or D-L-A structure).

For example, the sublimation temperature of the p-type semiconductor of the D-A structure (or D-L-A structure) that includes a fluorine may be about 3° C. or more, within the above range, about 5° C. or more, about 7° C. or more, or about 10° C. or more, within the above range, about 3° C. to about 50° C., about 5° C. to about 50° C., about 10° C. to about 50° C., about 3° C. to about 40° C., about 5° C. to about 40° C., about 10° C. to about 40° C., about 3° C. to about 30° C., about 5° C. to about 30° C. or about 10° C. to about 30° C., lower than the sublimation temperature of the p-type semiconductor of the same D-A structure that does not include a fluorine.

For example, the sublimation temperature of the p-type semiconductor of the D-A structure (or D-L-A structure) that includes a fluorine may be less than or equal to about 300° C., within the above range about 290° C., less than or equal to about 280° C., less than or equal to about 270° C., less than or equal to about 260° C., or less than or equal to about 250° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 300° C., about 150° C. to about 290° C., about 150° C. to about 280° C., about 150° C. to about 270° C., about 150° C. to about 260° C., about 150° C. to about 250° C., about 200° C. to about 300° C., about 200° C. to about 290° C., about 200° C. to about 280° C., about 200° C. to about 270° C., about 200° C. to about 260° C., or about 200° C. to about 250° C.

As an example, fluorine may be included in the substituent of the aromatic ring in the electron donating moiety (D) of the p-type semiconductor. For example, the substituent of the aromatic ring in the electron donating moiety (D) of the p-type semiconductor may be a fluorine; a fluorine-substituted C1 to C30 alkyl group; a fluorine-substituted C1 to C30 alkoxy group; a fluorine-substituted C1 to C30 alkylthio group; a fluorine-substituted C6 to C30 aryl group; a fluorine-substituted C3 to C30 heterocyclic group; or any combination thereof.

For example, the substituent of the aromatic ring in the electron donating moiety (D) of the p-type semiconductor may be fluorine; a fluorine-substituted methyl group; a fluorine-substituted ethyl group; a fluorine-substituted propyl group, a fluorine-substituted butyl group; a fluorine-substituted pentyl group; a fluorine-substituted hexyl group; a fluorine-substituted methoxy group; a fluorine-substituted ethoxy group; a fluorine substituted propoxy group; a fluorine-substituted phenyl group; a fluorine-substituted biphenyl group; a fluorine-substituted naphthyl group; a fluorine-substituted nitrogen-containing heterocyclic group; or any combination thereof. It may be substituted with 1 or 2 or more, for example 1, 2 or 3 fluorines.

For example, the fluorine-containing p-type semiconductor may be a light absorbing compound represented by any one of Chemical Formulas 1 to 4.

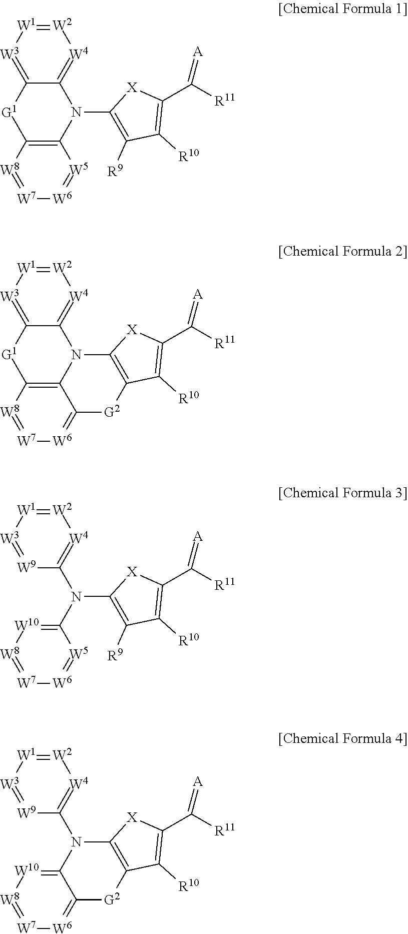

In Chemical Formulas 1 to 4,
X may be O, S, Se, Te, SO, SO₂, CR^{a}R^{b}, SiR^{c}R^{d}, or GeR^{e}R^{f},
W¹ to W¹⁰ may each independently be N or CR¹⁰⁰, wherein at least one of W¹ to W⁸ may be CR¹⁰⁰,
G 1 and G 2 may each independently be a single bond, O, S, Se, Te, CR^{g}R^{h}, SiRⁱR^{j}, or GeR^{k}R^{l},
A may be an electron accepting moiety,
R⁹ to R¹¹, R¹⁰⁰ and R^{a} to R^{l} may each independently be hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
at least one of R¹⁰⁰ and R^{g} to R^{l} may include a fluorine,
R⁹ to R¹¹, R¹⁰⁰, and R^{a} to R^{l} may each independently be present or an adjacent two of R⁹ to R¹¹, R¹⁰⁰, and R^{a} to R^{l} may be linked to each other to form a ring.

For example, at least one of R¹⁰⁰ and R^{g} to R^{l} may be a fluorine; a fluorine-substituted C1 to C30 alkyl group; a fluorine-substituted C1 to C30 alkoxy group; a fluorine-substituted C1 to C30 alkylthio group; a fluorine-substituted C6 to C30 aryl group; a fluorine-substituted C3 to C30 heterocyclic group; or any combination thereof.

For example, X may be O, S, Se or Te, such as S, Se or Te, for example Se or Te.

For example, G¹ and G² may be the same as or different from each other, for example, a single bond, CR^{g}R^{h}, SiRⁱR^{j}, or GeR^{k}R^{l}, or for example, a single bond or CR^{g}R^{h}.

For example, A of Chemical Formulas 1 to 4 may be a cyclic group including C═Z¹, a halogen, a C1 to C30 haloalkyl group, a cyano group, a dicyanovinyl group, or any combination thereof, wherein Z¹ may be O, S, Se, Te, or CR^{m}Rⁿ, wherein R^{m} and Rⁿ may each independently be hydrogen, deuterium, a substituted or unsubstituted C1 to C20 alkyl group, a carbonyl group, a cyano group, a dicyanovinyl group, or any combination thereof, and R^{m} and Rⁿ may each independently present or may be linked to each other to form a ring,

For example, A may be a cyclic group including C═Z¹, for example, a cyclic group represented by any one of Chemical Formulas AA to AE.

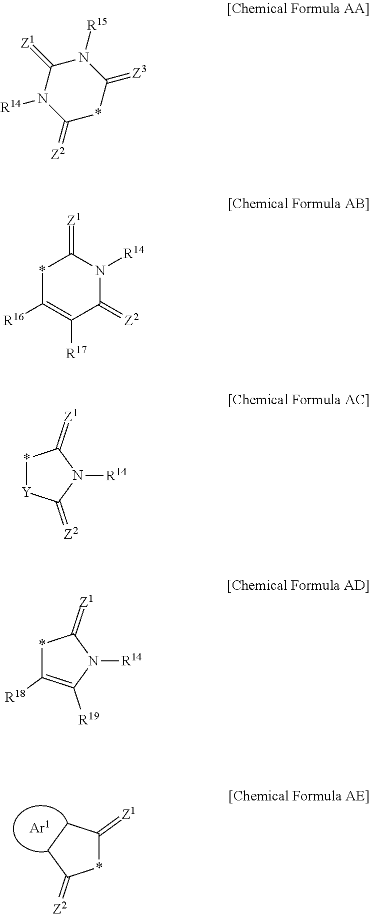

In Chemical Formulas AA to AE,
Z¹ to Z³ may each independently be O, S, Se, Te, or CR^{m}Rⁿ, wherein R^{m} and Rⁿ may each independently be hydrogen, deuterium, a substituted or unsubstituted C1 to C20 alkyl group, a carbonyl group, a cyano group, a dicyanovinyl group, or any combination thereof, and R^{m} and Rⁿ may each independently be present or may be linked to each other to form a ring,
Y may be O, S, Se, or Te,
Ar¹ may be a substituted or unsubstituted C6 to C30 arylene group, a substituted or unsubstituted C3 to C30 cycloalkylene group, a substituted or unsubstituted C3 to C30 cycloalkenylene group, a substituted or unsubstituted C2 to C30 heterocyclic group, or a fused ring thereof,
R¹⁴ to R¹⁹ may each independently be hydrogen, deuterium, a substituted or unsubstituted C1 to C20 alkyl group, a substituted or unsubstituted C2 to C30 alkenyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, or any combination thereof,
R¹⁴ to R¹⁹ may each independently be present or an adjacent two of R¹⁴ to R¹⁹ may be linked to each other to form a ring, and
* is a linking point with any one of Chemical Formulas 1 to 4.

For example, in Chemical Formula AA, Z¹, Z², and Z³ may be the same as or different from each other, and may each independently be O, S, Se, Te, CH(CN), C(CN)₂, or any combination thereof. For example, Z¹, Z², and Z³ may be the same as each other, and may each be O. For example, Z¹, Z², and Z³ may be the same as each other, and each may be S. For example, any one of Z¹, Z², and Z³ may be different, any two of Z¹, Z², and Z³ may be O and the other may be S, Se, Te, CH(CN), or C(CN)₂.

For example, R¹⁴ and R¹⁵ of Chemical Formula AA may be the same as or different from each other, and may each independently be hydrogen or a substituted or unsubstituted C1 to C30 alkyl group.

For example, in Chemical Formulas AB, AC, or AE, Z¹ and Z² may be the same as or different from each other, and may each independently be O, S, Se, Te, CH(CN), C(CN)₂, or any combination thereof. For example, Z¹ and Z² may be the same as each other, and may each be O. For example, Z¹ and Z² may be different from each other, and any one of Z¹ and Z² may be O and the other may be Se, Te, CH(CN), or C(CN)₂.

For example, R¹⁴ and R¹⁶ to R¹⁹ in Chemical Formulas AB, AC, or AD may each independently be hydrogen or a substituted or unsubstituted C1 to C30 alkyl group.

For example, the cyclic group represented by Chemical Formula AE may be a cyclic group represented by any one of Chemical Formulas AE-1 to AE-4 according to Ar¹.

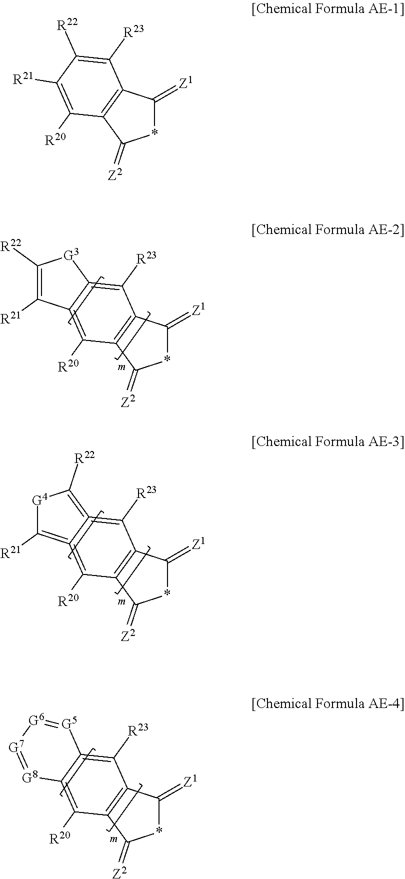

In Chemical Formulas AE-1 to AE-4,
Z¹ and Z² are the same as described above,
G³ and G4 may each independently be O, S, Se, or Te,
G⁵ to G⁸ may each independently be N or CR²⁴,
R²⁰ to R²³ may each independently be hydrogen, deuterium, a substituted or unsubstituted C1 to C20 alkyl group, a substituted or unsubstituted C2 to C30 alkenyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, or any combination thereof,
R²⁰ to R²³ may each independently be present or an adjacent two of R²⁰ to R²³ may be linked to each other to form a ring,
m may be an integer from 0 to 2, and
* is a linking point with any one of Chemical Formulas 1 to 4.

For example, in Chemical Formulas 1 to 4, W¹ to W¹⁰ may each be CR¹⁰⁰, and the fluorine-containing p-type semiconductor may be a light absorbing compound represented by any one of Chemical Formulas 1-1 to 4-1.

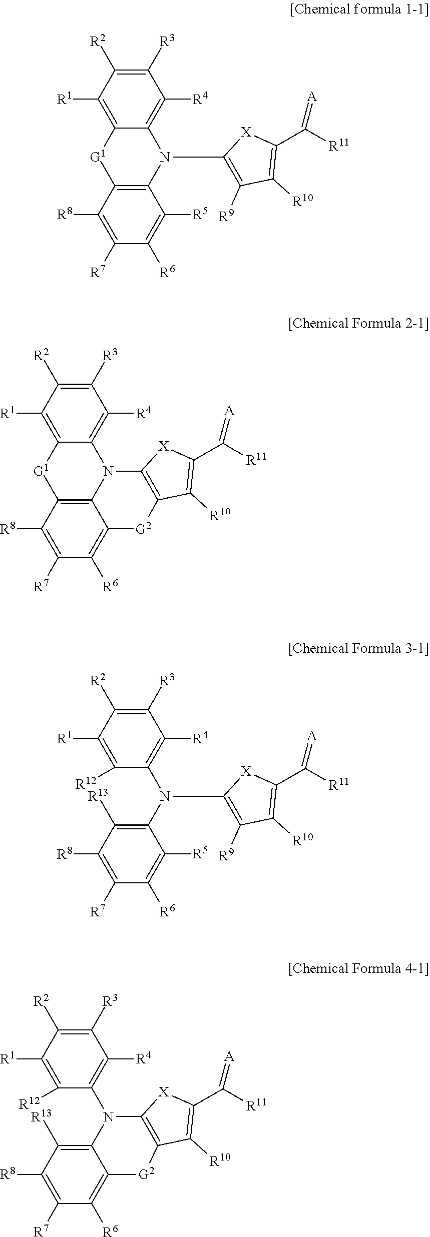

In Chemical Formulas 1-1 to 4-1,
X may be O, S, Se, Te, SO, SO2, CR^{a}R^{b}, SiR^{c}R^{d}, or GeR^{e}R^{f},
G¹ and G² may each independently be a single bond, O, S, Se, Te, CR^{g}R^{h}, SiRⁱR^{j}, or GeR^{k}R^{l},

A may be an electron accepting moiety, for example a cyclic group including C═Z¹, a halogen, a C1 to C30 haloalkyl group, a cyano group, a dicyanovinyl group, or any combination thereof, wherein Z¹ may be O, S, Se, Te, or CR^{m}Rⁿ, wherein R^{m} and Rⁿ may each independently be hydrogen, deuterium, a substituted or unsubstituted C1to C20 alkyl group, a carbonyl group, a cyano group, a dicyanovinyl group, or any combination thereof, and R^{m} and Rⁿ may each independently present or may be linked to each other to form a ring,
R¹ to R¹³ and R^{a} to R^{l} may each independently be hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
R¹ to R¹³ and R^{a} to R^{l} may each independently be present or an adjacent two of R¹ to R¹³ and R^{a} to R^{l} may be linked to each other to form a ring,
at least one of R¹ to R⁸ and R^{g} to R^{l} in Chemical Formula 1-1 or 2-1 may include a fluorine, and
at least one of R¹ to R⁸, R¹², R¹³, and R^{g} to R^{l} in Chemical Formula 3-1 or 4-1 may include a fluorine.

For example, at least one of R¹ to R⁸ and R^{g} to R^{l} in Chemical Formula 1-1 or 2-1 may include a fluorine, for example, one, two, or three of R¹ to R⁸ and R^{g} to R^{l} in Chemical Formula 1-1 or 2-1 may include a fluorine, and for example, any one of R¹ to R⁸ and R^{g} to R^{l} in Chemical Formula 1-1 or 2-1 may include a fluorine. For example, any one of R¹ to R⁴ of Chemical Formula 1-1 or 2-1 may include a fluorine.

For example, at least one of R², R³, R⁶, and R⁷ of Chemical Formulas 1-1 or 2-1 may include a fluorine, and for example, at least one of R² and R³ of Chemical Formulas 1-1 or 2-1 may include a fluorine. For example, any one of R² and R³ in Chemical Formulas 1-1 or 2-1 may include a fluorine.

For example, at least one of R¹ to R⁸, R¹², R¹³, and R^{g} to R^{l} of Chemical Formula 3-1 or 4-1 may include a fluorine, and for example, one, two, or three of R¹ to R⁸, R¹², R¹³, and R^{g} to R^{l} of Chemical Formula 3-1 or 4-1 may include a fluorine. For example, one of R¹ to R⁸, R¹² and R¹³ in Chemical Formulas 3-1 or 4-1 may include a fluorine, and for example, any one of R¹ to R⁴ and R¹² in Chemical Formulas 3-1 or 4-1 may include a fluorine.

For example, at least one of R², R³, R⁶, and R⁷ of Chemical Formulas 3-1 or 4-1 may include a fluorine, and for example, at least one of R² and R³ of Chemical Formulas 3-1 or 4-1 may include a fluorine. For example, any one of R² and R³ in Chemical Formulas 3-1 or 4-1 may include a fluorine.

For example, at least one of R¹ to R⁸ and R^{g} to R^{l} in Chemical Formulas 1-1 or 2-1 or at least one of R¹ to R⁸, R¹², R¹³, and R^{g} to ^{l} in Chemical Formulas 3-1 or 4-1 may be a fluorine; a fluorine-substituted C1 to C30 alkyl group; a fluorine-substituted C1 to C30 alkoxy group; a fluorine-substituted C1 to C30 alkylthio group; a fluorine-substituted C6 to C30 aryl group; a fluorine-substituted C3 to C30 heterocyclic group; or any combination thereof.

For example, at least one of R², R³, R⁶, and R⁷ in Chemical Formulas 1-1 to 4-1 may be a fluorine; a fluorine-substituted C1 to C30 alkyl group; a fluorine-substituted C1 to C30 alkoxy group; a fluorine-substituted C1 to C30 alkylthio group; a fluorine-substituted C6 to C30 aryl group; a fluorine-substituted C3 to C30 heterocyclic group; or any combination thereof.

For example, X may be O, S, Se, or Te, for example S, Se, or Te, for example Se or Te.

For example, G¹ and G² may be the same as or different from each other, for example, a single bond, CR^{g}R^{h}, SiRⁱR^{j}, or GeR^{k}R^{l}, or for example, a single bond or CRgRh.

For example, A may be a cyclic group including C═Z¹, for example, a cyclic group represented by any one of Chemical Formulas AA to AE.

For example, the fluorine-containing p-type semiconductor may be one of the compounds listed in Group 1, but is not limited thereto.

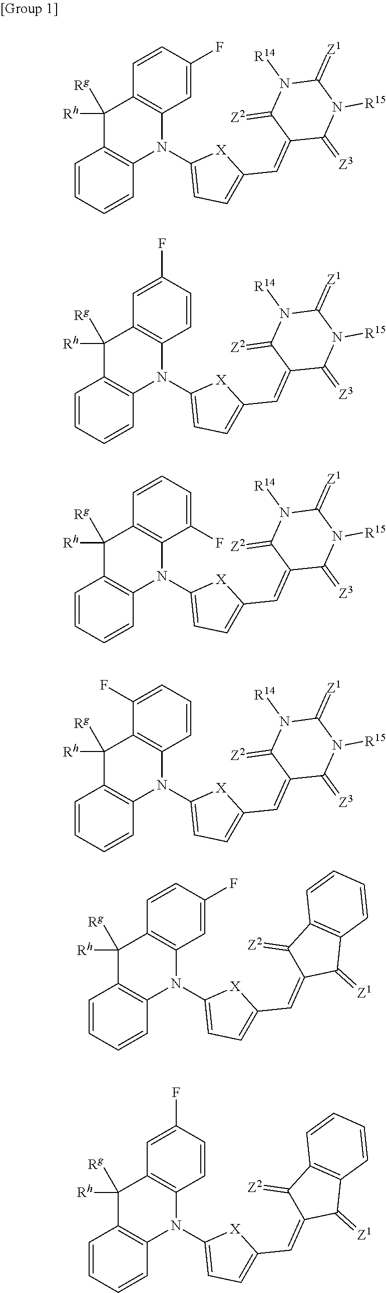

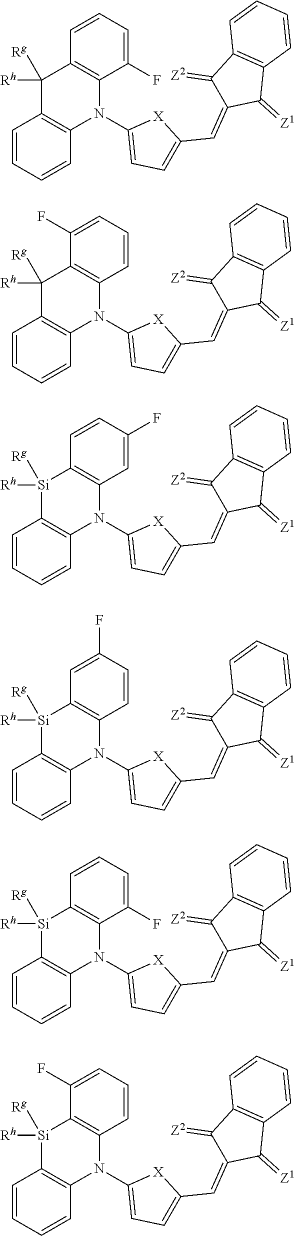

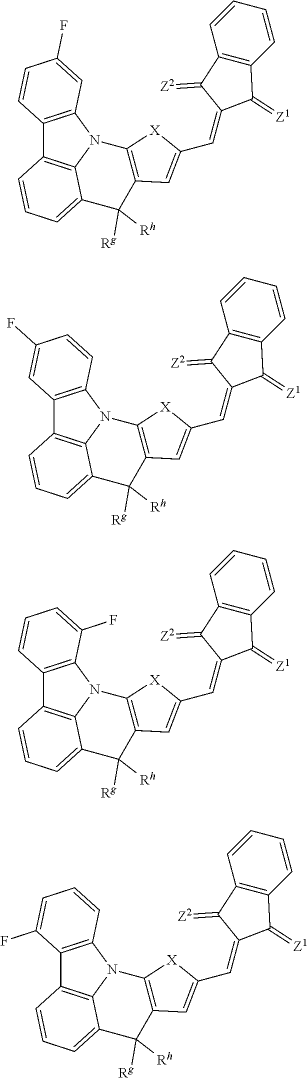

In Group 1, X, Z¹, Z², Z³, R^{g}, and R^{h} are the same as described above.

The aforementioned fluorine-containing p-type semiconductor may have an energy level capable of forming effective electrical matching with the first common auxiliary layer 350. For example, a difference between a HOMO energy level of the first common auxiliary layer 350 and a HOMO energy level of the fluorine-containing p-type semiconductor may be less than about 1.0 eV, within the above range, less than or equal to about 0.9 eV, less than or equal to about 0.8 eV, less than or equal to about 0.7 eV, or less than or equal to about 0.5 eV, greater than or equal to about 0 eV and less than about 1.0 eV, about 0 eV to about 0.9 eV, about 0 eV to about 0.8 eV, about 0 eV to about 0.7 eV, about 0 eV to about 0.5 eV, greater than or equal to about 0.01 eV and less than about 1.0 eV, about 0.01 eV to about 0.9 eV, about 0.01 eV to about 0.8 eV, about 0.01 eV to about 0.7 eV, or about 0.01 eV to about 0.5 eV. Accordingly, electric charges (e.g., holes) generated in the photosensitive layer 330 may pass through the first common auxiliary layer 350 to effectively move and/or be extracted to the pixel electrode 310.

The photosensitive layer 330 may further include an n-type semiconductor capable of forming a pn junction with the fluorine-containing p-type semiconductor in addition to the aforementioned fluorine-containing p-type semiconductor.

The n-type semiconductor may be, for example, a transparent material that does not substantially absorb light in a visible wavelength spectrum. The transparent material may have a wide energy bandgap such that it does not substantially absorb light in the visible wavelength spectrum. For example, it may have an energy bandgap of greater than or equal to about 2.5 eV, for example, about 2.5 eV to about 6.0 eV within the above range.

In addition, the n-type semiconductor may have an energy level capable of forming effective electrical matching with the second common auxiliary layer 340. For example, a difference between a LUMO energy level of the second common auxiliary layer 340 and a LUMO energy level of the n-type semiconductor may be less than about 1.0 eV, within the above range, less than or equal to about 0.9 eV, less than or equal to about 0.8 eV, less than or equal to about 0.7 eV, or less than or equal to about eV, greater than or equal to about 0 eV and less than about 1.0 eV, about 0 eV to about 0.9 eV, about 0 eV to about 0.8 eV, about 0 eV to about 0.7 eV, about 0 eV to about 0.5 eV, greater than or equal to about 0.01 eV and less than about 1.0 eV, about eV to about 0.9 eV, about 0.01 eV to about 0.8 eV, about 0.01 eV to about 0.7 eV, or about 0.01 eV to about 0.5 eV. Accordingly, electric charges (e.g., electrons) generated in the photosensitive layer 330 may pass through the second common auxiliary layer 340 to effectively move and/or be extracted to the common electrode 320. The LUMO energy level of the n-type semiconductor may be about 2.5 eV to about 3.5 eV, but is not limited thereto.

The fluorine-containing p-type semiconductor and the n-type semiconductor may have a relatively small difference in sublimation temperatures so that they may be deposited in the same chamber. For example, a difference between the sublimation temperature of fluorine-containing p-type semiconductor and n-type semiconductor may be less than about 150° C., within the above range, for example less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., less than or equal to about 20° C., less than or equal to about 15° C., or less than or equal to about 10° C., within the above range, greater than or equal to about 0° C. and less than about 150° C., about 0° C. to about 140° C., about 0° C. to about 130° C., about 0° C. to about 120° C., about 0° C. to about 110° C., about 0° C. to about 100° C., about 0° C. to about 90° C., about 0° C. to about 80° C., about 0° C. to about 70° C., about 0° C. to about 60° C., about 0° C. to about 50° C., about 0° C. to about 40° C., about 0° C. to about 30° C., about 0° C. to about 20° C., about 0° C. to about 15° C., about 0° C. to about 10° C., greater than or equal to about 2° C. and less than about 150° C., about 2° C. to about 140° C., about 2° C. to about 130° C., about 2° C. to about 120° C., about 2° C. to about 110° C., about 2° C. to about 100° C., about 2° C. to about 90° C., about 2° C. to about 80° C., 2° C. to about 70° C., about 2° C. to about 60° C., about 2° C. to about 50° C., about 2° C. to about 40° C., about 2° C. to about 30° C., about 2° C. to about 20° C., about 2° C. to about 15° C., or about 2° C. to about 10° C.

For example, the sublimation temperature of the n-type semiconductor may be less than or equal to about 400° C., within the above range, less than or equal to about 380° C., less than or equal to about 360° C., less than or equal to about 350° C., less than or equal to about 330° C., less than or equal to about 320° C., less than or equal to about 300° C., less than or equal to about 280° C., less than or equal to about 270° C., less than or equal to about 260° C., or less than or equal to about 250° C., about 100° C. to about 400° C., about 100° C. to about 380° C., about 100° C. to about 360° C., about 100° C. to about 350° C., about 100° C. to about 330° C., about 100° C. to about 320° C., about 100° C. to about 300° C., about 100° C. to about 280° C., about 100° C. to about 270° C., about 100° C. to about 260° C., about 100° C. to about 250° C., about 150° C. to about 400° C., about 150° C. to about 380° C., about 150° C. to about 360° C., about 150° C. to about 350° C., about 150° C. to about 330° C., about 150° C. to about 320° C., about 150° C. to about 300° C., about 150° C. to about 290° C., about 150° C. to about 280° C., about 150° C. to about 270° C., about 150° C. to about 260° C., about 150° C. to about 250° C., about 200° C. to about 400° C., about 200° C. to about 380° C., about 200° C. to about 360° C., about 200° C. to about 350° C., about 200° C. to about 330° C., about 200° C. to about 320° C., about 200° C. to about 300° C., about 200° C. to about 290° C., about 200° C. to about 280° C., about 200° C. to about 270° C., about 200° C. to about 260° C., or about 200° C. to about 250° C.

As an example, the sublimation temperature of the fluorine-containing p-type semiconductor and the n-type semiconductor may be less than or equal to about 400° C., respectively, and within the above range, about 100° C. to about 400° C., about 100° C. to about 350° C., or about 100° C. to about 300° C.

In order to satisfy these electrical and thermal characteristics, fullerenes such as C60 and C70, which are generally used as n-type semiconductors, may be excluded. Accordingly, the n-type semiconductor may be selected from non-fullerene n-type semiconductors, and may be a depositable low molecular weight organic semiconductor that satisfies the aforementioned electrical and thermal characteristics.

For example, the n-type semiconductor may be a compound represented by Chemical Formula 5 or 6.

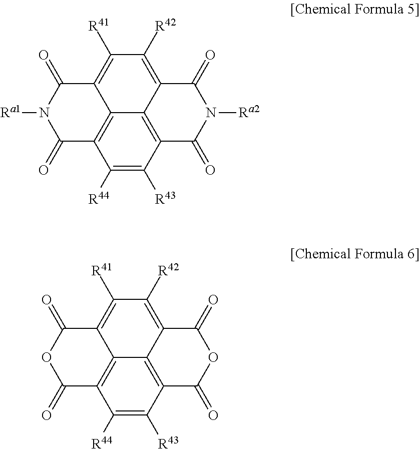

In Chemical Formulas 5 and 6,
R⁴¹ to R⁴⁴, R^{a1}, and R^{a2} are each independently hydrogen, a substituted or unsubstituted C1 to C30 alkyl group, a substituted or unsubstituted C6 to C30 aryl group, a substituted or unsubstituted C3 to C30 heterocyclic group, a halogen, a cyano group, or any combination thereof.

For example, at least one of R^{a1} or R^{a2} may include an electron withdrawn group, and for example at least one of R^{a1} or R^{a2} may include a halogen; a cyano group; a halogen-substituted C1 to C30 alkyl group; a halogen-substituted C6 to C30 aryl group; a halogen-substituted C3 to C30 heterocyclic group; a cyano-substituted C1 to C30 alkyl group; a cyano-substituted C6 to C30 aryl group; a cyano-substituted C3 to C30 heterocyclic group; a substituted or unsubstituted pyridinyl group; a substituted or unsubstituted pyrimidinyl group; a substituted or unsubstituted triazinyl group; a substituted or unsubstituted pyrazinyl group; a substituted or unsubstituted quinolinyl group; a substituted or unsubstituted isoquinolinyl group; a substituted or unsubstituted quinazolinyl group; a C1 to C30 alkyl group substituted with a substituted or unsubstituted pyridinyl group; a C6 to C30 aryl group substituted with a substituted or unsubstituted pyridinyl group; a C1 to C30 alkyl group substituted with a substituted or unsubstituted pyrimidinyl group; a C6 to C30 aryl group substituted with a substituted or unsubstituted pyrimidinyl group; a C1 to C30 alkyl group substituted with a substituted or unsubstituted triazinyl group; a C6 to C30 aryl group substituted with a substituted or unsubstituted triazinyl group; a C1 to C30 alkyl group substituted with a substituted or unsubstituted pyrazinyl group; a C6 to C30 aryl group substituted with a substituted or unsubstituted pyrazinyl group; a C1 to C30 alkyl group substituted with a substituted or unsubstituted quinolinyl group; a C6 to C30 aryl group substituted with a substituted or unsubstituted quinolinyl group; a C1 to C30 alkyl group substituted with a substituted or unsubstituted isoquinolinyl group; a C6 to C30 aryl group substituted with a substituted or unsubstituted isoquinolinyl group; a C1 to C30 alkyl group substituted with a substituted or unsubstituted quinazolinyl group; a C6 to C30 aryl group substituted with a substituted or unsubstituted quinazolinyl group; or any combination thereof.

The photosensitive layer 330 may include an intrinsic layer (I-layer) in which the aforementioned p-type semiconductor and n-type semiconductor are blended in a bulk heterojunction form, and may further include, for example, a p-type layer including the p-type semiconductor and an n-type layer including the aforementioned n-type semiconductor. The photosensitive layer 330 may be included in various combinations, for example, an I-layer, a p-type layer/I-layer, an I-layer/n-type layer, a p-type layer/I-layer/n-type layer, and the like. The intrinsic layer (I-layer) may be formed of, for example, a p-type semiconductor and an n-type semiconductor, and may be a co-deposited layer of a p-type semiconductor and an n-type semiconductor.

The photosensitive layer 330 may include a bi-layer (p-type layer/n-type layer) including a p-type layer including a p-type semiconductor and an n-type layer including the aforementioned n-type semiconductor. When the photosensitive layer 330 is a bi-layer (p-type layer/n-type layer), the p-type layer may be disposed close to the pixel electrode 310 and the n-type layer may be disposed close to the common electrode 320. The p-type layer may consist of a p-type semiconductor, and may be a single deposited layer of the p-type semiconductor. The n-type layer may consist of an n-type semiconductor, and may be a single deposited layer of the n-type semiconductor.

For example, the photosensitive layer 330 may include an intrinsic layer consisting of the aforementioned fluorine-containing p-type semiconductor represented by any one of Chemical Formulas 1 to 4 and a non-fullerene n-type semiconductor.

For example, the photosensitive layer 330 may include an intrinsic layer consisting of the aforementioned fluorine-containing p-type semiconductor represented by any one of Chemical Formulas 1 to 4 and the non-fullerene n-type semiconductor.

For example, the photosensitive layer 330 may include a first photosensitive layer (p-type layer) consisting of the fluorine-containing p-type semiconductor represented by any one of Chemical Formulas 1 to 4 and a second photosensitive layer (n-type layer) consisting of the aforementioned non-fullerene n-type semiconductor.

For example, the photosensitive layer 330 may include a first photosensitive layer (p-type layer) consisting of the fluorine-containing p-type semiconductor represented by any one of Chemical Formulas 1-1 to 4-1 and a second photosensitive layer (n-type layer) consisting of the non-fullerene n-type semiconductor.

For example, as described above, the light emitting layers 212, 222, and 232 of the light emitting elements 210, 220, and 230 may include organic light emitting materials, and the organic light emitting materials of the light emitting layers 212, 222, and 232 and the fluorine-containing p-type semiconductor and the non-fullerene n-type semiconductor of the photosensitive layer 330 may be vacuum-deposited in the same chamber. Accordingly, differences between the sublimation temperatures of the organic light emitting materials of the light emitting layers 212, 222, and 232, and the fluorine-containing p-type semiconductor and non-fullerene n-type semiconductor of the photosensitive layer 330 may be relatively small, and for example, the differences in the sublimation temperatures of the organic light emitting materials, fluorine-containing p-type semiconductor, and non-fullerene n-type semiconductor may be less than about 150° C., within the above range, for example less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., less than or equal to about 20° C., less than or equal to about 15° C., or less than or equal to about 10° C., within the above range, greater than or equal to about 0° C. and less than about 150° C., about 0° C. to about 140° C., about 0° C. to about 130° C., about 0° C. to about 120° C., about 0° C. to about 110° C., about 0° C. to about 100° C., about 0° C. to about 90° C., about 0° C. to about 80° C., about 0° C. to about 70° C., about 0° C. to about 60° C., about 0° C. to about 50° C., about 0° C. to about 40° C., about 0° C. to about 30° C., about 0° C. to about 20° C., about 0° C. to about 15° C., about 0° C. to about 10° C., greater than or equal to about 2° C. and less than about 150° C., about 2° C. to about 140° C., about 2° C. to about 130° C., about 2° C. to about 120° C., about 2° C. to about 110° C., about 2° C. to about 100° C., about 2° C. to about 90° C., about 2° C. to about 80° C., about 2° C. to about 70° C., about 2° C. to about 60° C., about 2° C. to about 50° C., about 2° C. to about 40° C., about 2° C. to about 30° C., about 2° C. to about 20° C., about 2° C. to about 15° C., or about 2° C. to about 10° C.

For example, the sublimation temperatures of the organic light emitting materials of the light emitting layers 212, 222, and 232 may be less than or equal to about 350° C., within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., or about 150° C. to about 250° C.

For example, the sublimation temperatures of the organic light emitting materials of the light emitting layers 212, 222, and 232, the fluorine-containing p-type semiconductor and the non-fullerene n-type semiconductor of the photosensitive layer 330 may be less than or equal to about 350° C., or less than or equal to about 300° C. respectively, and within the above range, about 100° C. to about 350° C. or about 100° C. to about 300° C.

As described above, the p-type semiconductor and n-type semiconductor of the photosensitive layer 330 may achieve effective electrical matching with the first and second common auxiliary layers 350 and 340, respectively. Since the organic light emitting materials of the light emitting layers 212, 222, and 232 and the p-type semiconductor and n-type semiconductor of the photosensitive layer 330 have thermal characteristics in a similar range, the sensor may be effectively embedded in the display panel without deterioration of electrical characteristics and complexity of the process.

Each thickness of the light emitting layers 212, 222, and 232 and the photosensitive layer 330 may each independently be about 5 nm to about 300 nm, about 10 nm to about 250 nm, about 20 nm to about 200 nm, or about 30 nm to about 180 nm within the above range. Differences between the thicknesses of the light emitting layers 212, 222, and 232 and the photosensitive layer 330 may be less than or equal to about 20 nm, less than or equal to about 15 nm, less than or equal to about 10 nm, or less than or equal to about 5 nm within the above range, and the thicknesses of the light emitting layers 212, 222, and 232 and the photosensitive layer 330 may be substantially the same.

On the first, second and third light emitting elements 210, 220, and 230 and the photosensor 300, the encapsulation layer 50 is formed. The encapsulation layer may include, for example, a glass plate, a metal thin film, an organic layer, an inorganic layer, an organic/inorganic layer, or any combination thereof. The organic layer may include, for example, an acrylic resin, a (meth)acrylic resin, polyisoprene, a vinyl resin, an epoxy resin, an urethane resin, a cellulose resin, a perylene resin, or any combination thereof, but is not limited thereto. The inorganic layer may include, for example, oxide, nitride, and/or oxynitride, for example, silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or any combination thereof, but is not limited thereto. The organic/inorganic layer may include, for example, polyorganosiloxane but is not limited thereto. The encapsulation layer 50 may have one layer or two or more layers.

As described above, the sensor-embedded display panel 1000 according to some example embodiments includes the first, second, and third light emitting elements 210, 220, and 230 configured to emit light in a desired and/or alternatively predetermined wavelength spectrum to display colors, and the photosensor 300 configured to absorb light generated by reflection of the light, by the recognition target and convert the absorbed light into an electrical signal, in the same plane on the substrate 110, thereby performing a display function and a recognition function (e.g., biometric recognition function). Accordingly, unlike conventional display panels formed outside the display panel or formed under the display panel by manufacturing the sensor as a separate module, it may improve performance without increasing the thickness, implementing a slim-type high performance sensor-embedded display panel 1000.

In addition, since the photosensor 300 uses light emitted from the first, second, and third light emitting elements 210, 220, and 230, a recognition function (e.g., biometric recognition function) may be performed without a separate light source. Therefore, it is not necessary to provide a separate light source outside the display panel, thereby limiting and/or preventing a decrease in the aperture ratio of the display panel due to the area occupied by the light source, and at the same time saving power consumed by the separate light source to improve power consumption.

In addition, since the photosensors 300 may be anywhere in the non-display area NDA, they may be at a desired location of the sensor-embedded display panel 1000 as many as desired. Therefore, for example, by randomly or regularly arranging the photosensor 300 over the entire sensor-embedded display panel 1000, the biometric recognition function may be performed on any portion of the screen of an electronic device such as a mobile device and the biometric recognition function may be selectively performed only in a specific location where the biometric recognition function is required.

In addition, as described above, the first, second, and third light emitting elements 210, 220, and 230 and the photosensor 300 share the common electrode 320, the first common auxiliary layer 350, and the second common auxiliary layer 340 and thus the structure and process may be simplified compared with the case where the first, second, and third light emitting elements 210, 220, and 230 and the photosensor 300 are formed in separate processes.

In addition, as described above, the organic light emitting material included in the light emitting layers 212, 222, and 232 of the first, second, and third light emitting elements 210, 220, and 230 and the p-type semiconductor and n-type semiconductor included in the photosensitive layer 330 of the photosensor 300 have a sublimation temperature within the desired and/or alternatively predetermined ranges and may be deposited in a continuous process in the same chamber. Accordingly, the first, second, and third light emitting elements 210, 220, and 230 and the photosensor 300 may be manufactured in one process and thus realize a display panel conducting both a display function and a recognition function (e.g., a biometric recognition function) without a substantial additional process.

In addition, the photosensor 300 may be an organic sensor including an organic photosensitive layer and have more than twice light absorption, compared with an inorganic diode such as a silicon photodiode, and thus a higher sensing function with a thinner thickness.

In addition, as described above, by including the fluorine-containing p-type semiconductor in the photosensitive layer 330 of the photosensor 300, the light absorption characteristics and the resulting photoelectric conversion characteristics are improved, and the sublimation temperature (deposition temperature) is lowered to improve stability and processibility of the compound.

The aforementioned sensor-embedded display panel 1000 may be applied to electronic devices such as various display devices. Electronic devices such as display devices may be applied to, for example, mobile phones, video phones, smart phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

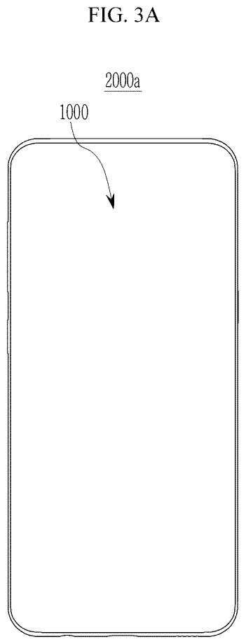

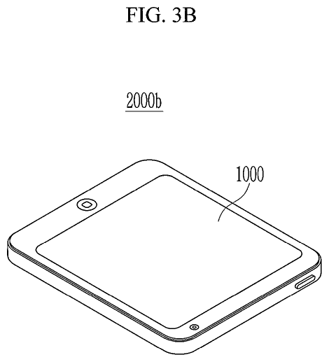

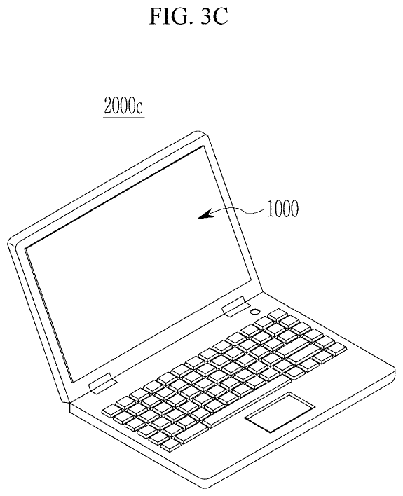

FIG. 3A is a schematic view illustrating an example of a smart phone as an electronic device according to some example embodiments.

Referring to FIG. 3A, the electronic device 2000a according to some example embodiments may include the aforementioned sensor-embedded display panel 1000, and the photosensor 300 in the whole or a portion of the sensor-embedded display panel 1000, and thus a biometric recognition function may be performed on any portion of the screen, and according to the user's selection, the biometric recognition function may be selectively performed only at a specific location where the biometric recognition function is required.

An example of a method of recognizing the recognition target 40 in an electronic device 2000a such as a display device may include, for example, driving the first, second, and third light emitting elements 210, 220, and 230 of the sensor-embedded display panel 1000 and the photosensor 300 to detect the light reflected from the recognition target 40 among the light emitted from the first, second, and third light emitting elements 210, 220, and 230, in the photosensor 300; comparing the image of the recognition target 40 stored in advance with the image of the recognition target 40 detected by the photosensor 300; and judging the consistency of the compared images and if they match according to the determination that recognition of the recognition target 40 is complete, turning off the photosensor 300, permitting user's access to the display device, and driving the sensor-embedded display panel 1000 to display an image.

While FIG. 3A illustrates an example of a smart phone as an electronic device according to some example embodiments, example embodiments are not limited thereto and inventive concepts may be embodied in other types of electronic devices. For example, as depicted in FIGS. 3B and 3C, according to some example embodiments, an electronic device 2000b in the form of a tablet device and an electronic device 2000c in the form of a computer may include the aforementioned sensor-embedded display panel 1000, and the photosensor 300 in the whole or a portion of the sensor-embedded display panel 1000, and thus a biometric recognition function may be performed on any portion of the screen, and according to the user's selection, the biometric recognition function may be selectively performed only at a specific location where the biometric recognition function is required.

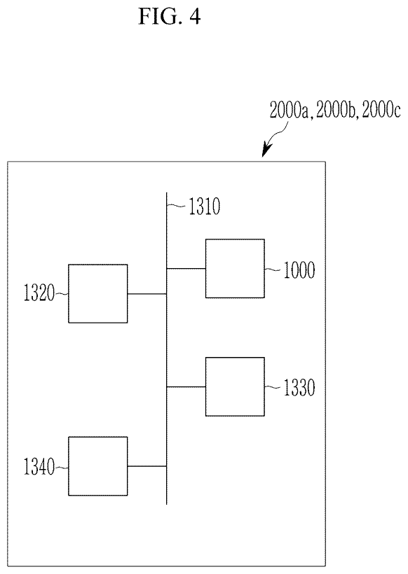

FIG. 4 is a schematic view illustrating an example of a configuration view of an electronic device according to some example embodiments.

Referring to FIG. 4, in addition to the aforementioned constituent elements, the electronic device 2000a, 2000b, or 2000c may further include a bus 1310, a processor 1320, a memory 1330, and at least one additional device 1340. Information of the aforementioned sensor-embedded display panel 1000, processor 1320, memory 1330, and at least one additional device 1340 may be transmitted to each other through the bus 1310.

The processor 1320 may include one or more processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may, for example, control a display operation of the sensor-embedded display panel 1000 or control a sensor operation of the photosensor 300.

The memory 1330 may store an instruction program, and the processor 1320 may perform a function related to the sensor-embedded display panel 1000 by executing the stored instruction program.

The one or more additional devices 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to the foregoing embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for the present embodiment or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of the aforementioned embodiments.

Hereinafter, the embodiments are illustrated in more detail with reference to examples. However, these examples are non-limiting, and the present scope is not limited thereto.

### SYNTHESIS EXAMPLE I: SYNTHESIS P-TYPE SEMICONDUCTOR

### Reference Synthesis Example 1

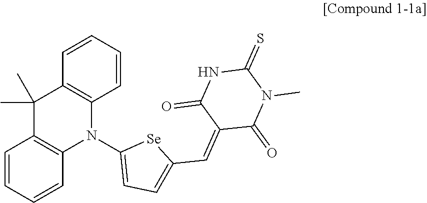

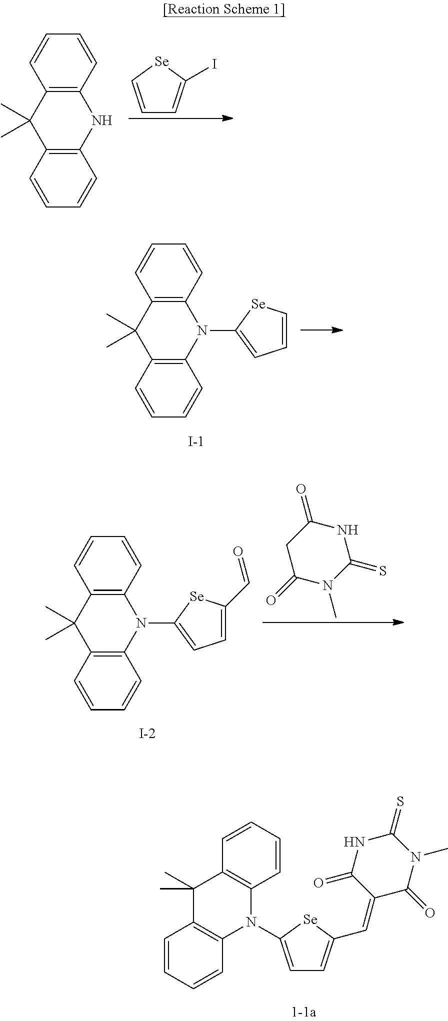

### (i) Synthesis of Compound 1-1 (9,9-dimethyl-10-(selenophen-2-yl)-9,10-dihydroacridine)

7.01 g (27.3 mmol) of 2-iodoselenophene and 5.59 g (24.8 mmol) of 9,9-dimethyl-9,10-dihydroacridine are heated under reflux in 150 ml of anhydrous toluene under presence of 5 mol % of Pd(dba)₂, 5 mol % of P(t-Bu)₃, and 7.15 g (74.4 mmol) of NaOtBu for 2 hours. The obtained product is separated and purified through silica gel column chromatography (toluene:hexane=1:4 in a volume ratio), obtaining 8.0 g (yield: 80%) of Compound I-1 (9,9-dimethyl-10-(selenophen-2-yl)-9,10-dihydroacridine).

### (ii) Synthesis of Compound 1-2 ((5-(9,9-dimethylacridin-10(9H)-yl)selenophene-2-carbaldehyde)

1.11 ml of phosphoryl chloride is added dropwise to 3.19 ml of N,N-dimethyl formamide at −15° C. and then, stirred at room temperature (24° C.) for 2 hours. The obtained mixture is slowly added dropwise to a mixture of 200 ml of dichloromethane and 3.19 g of Compound 1-1 (9,9-dimethyl-10-(selenophen-2-yl)-9,10-dihydroacridine) at −15° C. and then, stirred at room temperature (24° C.) for 30 minutes and concentrated under a reduced pressure. Subsequently, 100 ml of water is added thereto, and an aqueous sodium hydroxide solution is added thereto until pH reaches 14 and then, stirred at room temperature (24° C.) for 2 hours. An organic layer extracted with dichloromethane is washed with an aqueous sodium chloride solution and dried with magnesium sulfate anhydrous. The obtained product is separated and purified through silica gel column chromatography (hexane: ethylacetate=4:1 in a volume ratio), obtaining 2.20 g (yield: 73%) of Compound I-2 (5-(9,9-dimethylacridin-10(9H)-yl)selenophene-2-carbaldeheyde).

### (iii) Synthesis of Compound 1-1a

1.77 g (4.64 mmol) of Compound I-2 (5-(9,9-dimethylacridin-10(9H)-yl)selenophene-2-carbaldehyde) is suspended in ethanol, 0.89 g of 1-methyl-2-thioxodihydropyrimidine-4,6(1H,5H)-dione (5.57 mmol) is added thereto and then, reacted at 50° C. for 2 hours, obtaining 2.0 g (yield: 83%) of Compound 1-1a. The obtained compound is purified by sublimation to a purity of 99.9%.

1H-NMR (500 MHz, DMSO-d6): δ 12.1 (d, 1 H), 8.29 (d, 1 H), 8.22 (dd,1 H), 7.89 (dd, 2H) 7.76 (d, 2H), 7.61 (q, 2H), 7.48 (q, 2H), 6.59 (t, 1 H), 3.48 (d, 3H), 0.44 (s, 6H).

### Synthesis Example 1-1

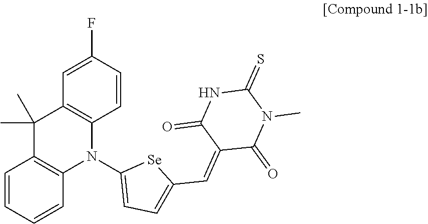

Compound 1-1 b (yield: 80%) is obtained in the same manner as in Reference Synthesis Example 1 except that 2-fluoro-9,9-dimethyl-9,10-dihydroacridine is used instead of the 9,9-dimethyl-9,10-dihydroacridine in the step (i).

1H-NMR (300 MHz, DMSO-d6): δ 10.96 (s, 1H), 7.87 (s, 1H), 7.19-7.14 (m, 5H), 6.96 (m, 2H) 6.83 (dd, 1 H), 6.59 (s, 1 H), 3.52 (s, 3H), 1.69 (s, 6H).

### Synthesis Example 1-2

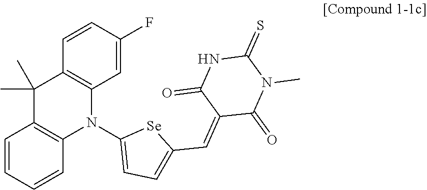

Compound 1-1c (yield: 80%) is obtained in the same manner as in Reference Synthesis Example 1 except that 3-fluoro-9,9-dimethyl-9,10-dihydroacridine is used instead of the 9,9-dimethyl-9,10-dihydroacridine in the step (i).

1H-NMR (300 MHz, DMSO-d6): δ 10.96 (s, 1H), 7.87 (s, 1H), 7.27-7.12 (m, 6H), 6.95 (m, 1 H) 6.81 (t, 1 H), 6.59 (s, 1H), 3.52 (s, 3H), 1.69 (s, 6H).

### Synthesis Example 1-3

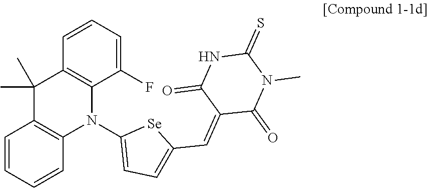

Compound 1-1d (yield: 80%) is obtained in the same manner as in Reference Synthesis Example 1 except that 4-fluoro-9,9-dimethyl-9,10-dihydroacridine is used instead of the 9,9-dimethyl-9,10-dihydroacridine in the step (i).

1H-NMR (300 MHz, DMSO-d6): δ 10.96 (s, 1H), 7.87 (s, 1H), 7.19-7.14 (m, 4H), 6.98-6.91 (m, 4H) 6.59 (s, 1H), 3.52 (s, 3H), 1.69 (s, 6H).

### Reference Synthesis Example 2

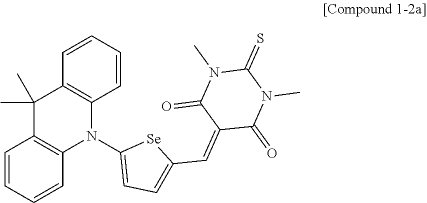

Compound 1-2a (yield: 80%) is obtained in the same manner as in Reference Synthesis Example 1 except that 1,3-dimethyl-2-thioxodihydropyrimidine-4,6(1H,5H)-dione is used instead of the 1-methyl-2-thioxodihydropyrimidine-4,6(1H,5H)-dione in the step (iii).

1H-NMR (300 MHz, DMSO-d6): 6 7.87 (s, 1H), 7.19-7.14 (m,7H), 6.95 (m, 2H)

6.59 (s, 1H), 3.52 (s, 6H), 1.69 (s, 6H).

### Synthesis Example 2-1

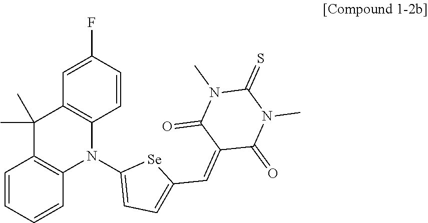

Compound 1-2b (yield: 80%) is obtained in the same manner as in Reference Synthesis Example 2 except that 2-fluoro-9,9-dimethyl-9,10-dihydroacridine is used instead of the 9,9-dimethyl-9,10-dihydroacridine in the step (i).

1H-NMR (300 MHz, DMSO-d6): δ 7.87 (s, 1H), 7.19-7.14 (m, 5H), 6.96 (m, 2H) 6.83 (dd, 1H), 6.59 (s, 1 H), 3.52 (s, 6H), 1.69 (s, 6H).

### Synthesis Example 2-2

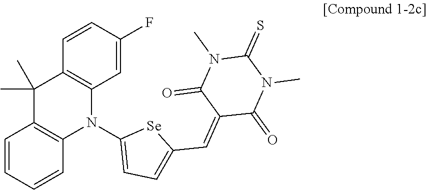

Compound 1-2c (yield: 80%) is obtained in the same manner as in Reference Synthesis Example 2 except that 3-fluoro-9,9-dimethyl-9,10-dihydroacridine is used instead of the 9,9-dimethyl-9,10-dihydroacridine in the step (i).

1H-NMR (300 MHz, DMSO-d6): δ 7.87 (s, 1H), 7.27-7.12 (m, 6H), 6.95 (m, 1 H) 6.81 (t, 1 H), 6.59 (s, 1 H), 3.52 (s, 6H), 1.69 (s, 6H).

### Synthesis Example 2-3

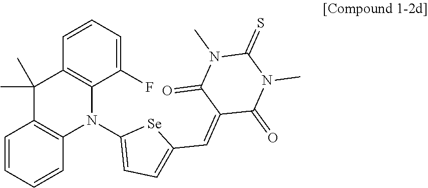

Compound 1-2d (yield: 80%) is obtained in the same manner as in Reference Synthesis Example 2 except that 4-fluoro-9,9-dimethyl-9,10-dihydroacridine is used instead of the 9,9-dimethyl-9,10-dihydroacridine in the step (i).

1H-NMR (300 MHz, DMSO-d6): δ 7.87 (s, 1H), 7.19-7.14 (m, 4H), 6.98-6.91 (m, 4H) 6.59 (s, 1 H), 3.52 (s, 6H), 1.69 (s, 6H).

### Reference Synthesis Example 3

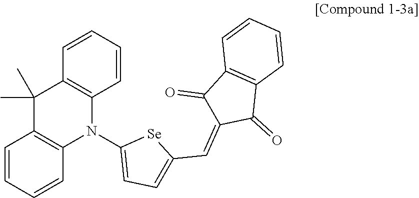 [SMILES: CC1(C)c2ccccc2N(c2ccc(C=C3C(=O)c4ccccc4C3=O)[se]2)c2ccccc21]

Compound 1-3a (yield: 80%) is obtained in the same manner as in Reference Synthesis Example 1 except that 1H-indene-1,3(2H)-dione is used instead of the 1-methyl-2-thioxodihydropyrimidine-4,6(1 H,5H)-dione in the step (iii).

1H-NMR (300 MHz, DMSO-d6): δ 8.32 (s, 1H), 7.71 (s, 4H), 7.19-7.14 (m, 7H), 6.95 (m, 2H) 6.59 (s, 1H), 1.69 (s, 6H).

### Synthesis Example 3-1

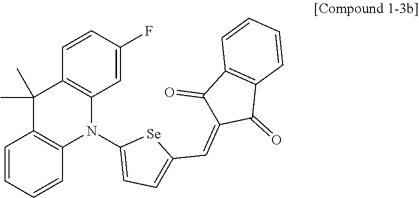 [SMILES: CC1(C)c2ccccc2N(c2ccc(C=C3C(=O)c4ccccc4C3=O)[se]2)c2cc(F)ccc21]

Compound 1-3b (yield: 80%) is obtained in the same manner as in Reference Synthesis Example 3 except that 2-fluoro-9,9-dimethyl-9,10-dihydroacridine is used instead of the 9,9-dimethyl-9,10-dihydroacridine in the step (i).

1H-NMR (300 MHz, DMSO-d6): δ 8.32 (s, 1 H), 7.71 (s, 4H), 7.27-7.12 (m, 6H), 6.95 (m, 1 H) 6.81 (t, 1 H), 6.59 (s, 1H), 1.69 (s, 6H).

### Reference Synthesis Example 4

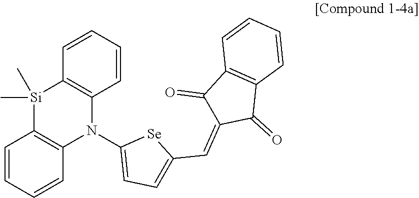 [SMILES: C[Si]1(C)c2ccccc2N(c2ccc(C=C3C(=O)c4ccccc4C3=O)[se]2)c2ccccc21]

Compound 1-4a (yield: 80%) is obtained in the same manner as in Reference Synthesis Example 3 except that 10,10-dimethyl-5,10-dihydrodibenzo[b,e][1,4]azasiline is used instead of the 9,9-dimethyl-9,10-dihydroacridine in the step (i).

1H-NMR (300 MHz, DMSO-d6): δ 8.32 (s, 1 H), 7.71 (s, 4H), 7.41 (m, 4H), 7.28 (dd, 2H) 7.14 (s, 1H), 7.03 (t, 2H), 6.59 (s, 1H), 0.66 (s, 6H).

### Synthesis Example 4-1

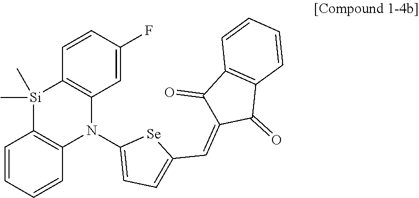 [SMILES: C[Si]1(C)c2ccccc2N(c2ccc(C=C3C(=O)c4ccccc4C3=O)[se]2)c2cc(F)ccc21]

Compound 1-4b (yield: 80%) is obtained in the same manner as Reference Synthesis Example 4 except that 3-fluoro-10,10-dimethyl-5,10-dihydrodibenzo[b,e][1,4]azasiline is used instead of the 10,10-dimethyl-5,10-dihydrodibenzo[b,e][1,4]azasiline in the step (i).

1H-NMR (300 MHz, DMSO-d6): δ 8.32 (s, 1H), 7.71 (s, 4H), 7.40 (m, 4H), 7.28 (dd, 1H), 7.14 (s, 1H), 7.03 (t, 1H), 6.96 (t, 1H), 6.59 (s, 1H), 0.66 (s, 6H).

### Reference Synthesis Example 5

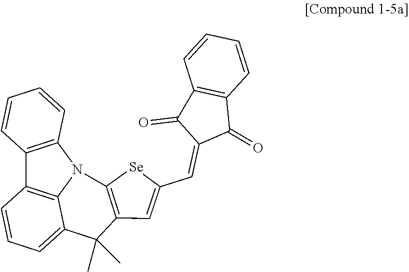 [SMILES: CC1(C)c2cc(C=C3C(=O)c4ccccc4C3=O)[se]c2-n2c3ccccc3c3cccc1c32]

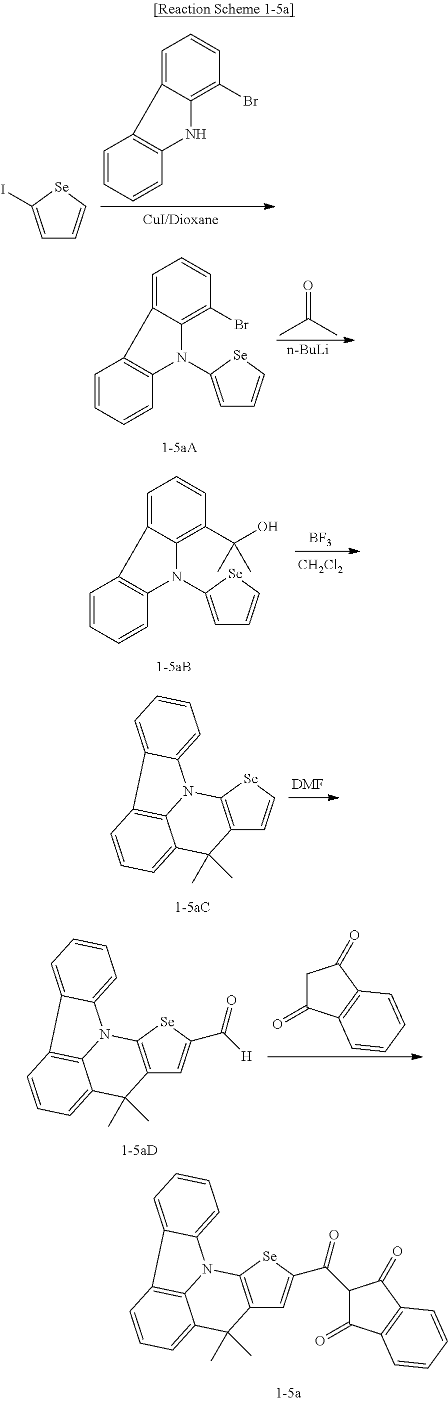

### (i) Synthesis of Compound 1-5aA

9.4 g (36.5 mmol) of 2-iodoselenophene and 7.5 g (30.5 mmol) of 1-bromo-9H-carbazole are dissolved in 30 ml of dioxane. Subsequently, 0.29 g (1.52 mmol) of coper(I) iodide, 0.70 g (6.09 mmol) of trans-1,2-cyclohexanediamine, and 12.9 g (61.0 mmol) of tripotassium phosphate are added thereto and then, heated under reflux for 30 hours. The obtained product is separated and purified through silica gel column chromatography (hexane:ethyl acetate=5:1 in a volume ratio), obtaining 8.18 g (yield: 72%) of Compound 1-5aA.

### (ii) Synthesis of Compound 1-5aB

12.0 g (32.0 mmol) of Compound 1-5aA is dissolved in 300 ml of dehydrated diethyl ether. Subsequently, 12 ml (32.0 mmol) of a 2.76 M n-BuLi hexane solution is added dropwise to the solution at −50° C. and then, stirred at room temperature for 1 hour. Subsequently, 2.0 g (35.2 mmol) of dehydrated acetone (dimethyl ketone (CH₃COCH₃)) is added thereto at −50° C. and then, stirred at room temperature for 2 hours. Subsequently, an organic layer extracted from the diethyl ether is washed with an aqueous sodium chloride solution and then, dried with magnesium sulfate anhydrous. The obtained product is separated and purified through silica gel column chromatography (hexane:dichloromethane=100:0 to 50:50 in a volume ratio), obtaining 6.3 g (yield: 56%) of Compound 1-5aB.

### (iii) Synthesis of Compound 1-5aC

6.23 g (17.6 mmol) of Compound 1-5aB is dissolved in 180m1 of dichloromethane. Subsequently, 4.98 g (35.5 mmol) of a boron trifluoride-ethyl ether complex is added dropwise thereto at 0° C. and then, stirred for 2 hours. An organic layer extracted from the dichloromethane is washed with an aqueous sodium chloride solution and dried with magnesium sulfate anhydrous. Subsequently, the obtained product is separated and purified through silica gel column chromatography (hexane:dichloromethane=50 : 50 in a volume ratio), obtaining 5.12 g (yield: 87%) of Compound 1-5aC.

### (iv) Synthesis of Compound 1-5aD

1.9 ml (20.2 mmol) of phosphoryl chloride is added dropwise to 6.0 ml (77.5 mmol) of N,N-dimethyl formamide at −15° C. and then, stirred at room temperature for 2 hours. This solution is slowly added dropwise to 150 ml of a dichloromethane solution of 5.23 g (15.5 mmol) of Compound 1-5aC at −15° C. and then, stirred at room temperature for 30 hours and concentrated under a low pressure. Subsequently, water is added thereto, and an aqueous sodium hydroxide solution is added thereto, until pH reaches 14, and then, stirred at room temperature for 2 hours. An organic layer extracted from the dichloromethane is washed with an aqueous sodium chloride solution and dried with magnesium sulfate anhydrous. The obtained product is separated and purified through silica gel column chromatography (hexane:dichloromethane=50 : 50 in a volume ratio), obtaining 3.34 g (yield: 65%) of Compound 1-5aD.

### (v) Synthesis of Compound Represented by Chemical Formula 1-5a

1.50 g (4.11 mmol) of Compound 1-5aD is dissolved in 20 ml of tetrahydrofuran, and 0.72 g (4.93 mmol) of 1H-indene-1,3(2H)-dione is added thereto and then, stirred at 50° C. for 4 hours and concentrated under a reduced pressure. Subsequently, chloroform and ethanol are used for recrystallization, obtaining 2.03 g (yield: 74%) of Compound 1-5a. The compound is purified by sublimation to purity of 99.9%.

¹H-NMR (300 MHz, Methylene Chloride-d₂): δ 8.15 (d, 1H), 8.14 (s, 1H), 8.07 (s, 1H), 8.03 (d, 1 H), 7.95-7.88 (m, 3H), 7.82-7.77 (m, 2H), 7.72 (td, 1H), 7.45-7.55 (m, 3H), 1.79 (s, 6H).

### Synthesis Example 5-1

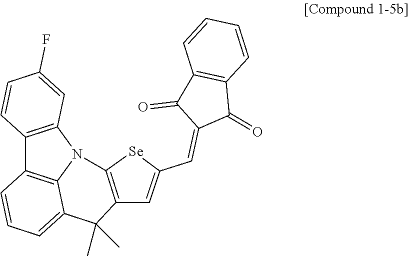 [SMILES: CC1(C)c2cc(C=C3C(=O)c4ccccc4C3=O)[se]c2-n2c3cc(F)ccc3c3cccc1c32]

Compound 1-5b (yield: 70%) is obtained in the same manner as Reference Synthesis Example 5 except that 1-bromo-7-fluoro-9H-carbazole is used instead of the 1-bromo-9H-carbazole in the step (1).

¹H-NMR (300 MHz, DMSO-d₆): δ 8.41(dd, 1H), 8.32 (s, 1H), 8.19 (dd, 1H), 7.71 (m, 5H), 7.52 (dd, 1H), 7.10 (S, 1H), 7.08 (t, 1H), 6.98 (td, 1H), 1.46 (s, 6H).

### Reference Synthesis Example 6

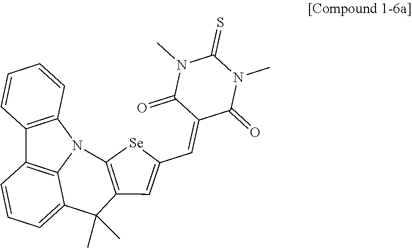 [SMILES: CN1C(=O)C(=Cc2cc3c([se]2)-n2c4ccccc4c4cccc(c42)C3(C)C)C(=O)N(C)C1=S]

Compound 1-6a (yield: 70%) is obtained in the same manner as in Reference Synthesis Example 5 except that 1,3-dimethyl-2-thioxodihydropyrimidine-4,6(1H,5H)-dione is used instead of the 1H-indene-1,3(2H)-dione in the step (v).

¹H-NMR (300 MHz, DMSO-d₆): δ 8.55 (d, 1H), 8.19 (d, 1H), 8.11 (d, 1H), 7.87 (s, 1H), 7.71 (d, 1H), 7.36 (t, 1H), 7.16-7.08 (m, 3H), 3.52 (s, 6H), 1.46 (s, 6H).

### Synthesis Example 6-1

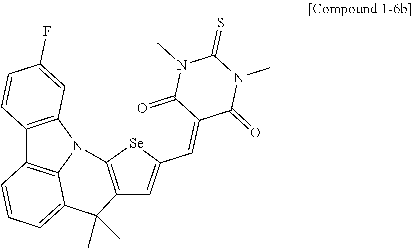 [SMILES: CN1C(=O)C(=Cc2cc3c([se]2)-n2c4cc(F)ccc4c4cccc(c42)C3(C)C)C(=O)N(C)C1=S]

Compound 1-6b (yield: 70%) is obtained in the same manner as in Reference Synthesis Example 6 except that 1-bromo-7-fluoro-9H-carbazole is used instead of the 1-bromo-9H-carbazole in the step (1).

¹H-NMR (300 MHz, DMSO-d₆): δ 8.41 (d, 1H), 8.19 (d, 1H), 7.87 (s, 1H), 7.71 (d, 1H), 7.52 (d, 1H), 7.10 (s, 1H), 7.08 (t, 1H), 6.98 (t, 1H), 3.52 (s, 6H), 1.46 (s, 6H).

### SYNTHESIS EXAMPLE II: SYNTHESIS OF N-TYPE SEMICONDUCTOR

### Synthesis Example 7

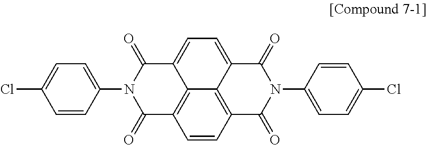 [SMILES: O=C1c2ccc3c4c(ccc(c24)C(=O)N1c1ccc(Cl)cc1)C(=O)N(c1ccc(Cl)cc1)C3=O]

A mixture of 1,4,5,8-naphthalenetetracarboxylic dianhydride (1 eq.) and 4-chloroaniline (2.2 eq.) is dissolved in a dimethyl formamide (DMF) solvent and then, put in a two-necked and round-bottomed flask and stirred at 180° C. for 24 hours. Subsequently, after decreasing the temperature to room temperature, methanol is added thereto to produce a product, and the product is filtered, obtaining a powder-type material. Then, the material is several times washed with methanol and purified by recrystallization with ethyl acetate and dimethylsulfoxide (DMSO). The obtained product is put in an oven and dried under vacuum at 80° C. for 24 hours, obtaining Compound 2-1a. A yield is 50% or more.

¹H-NMR (300 MHz, CDCl₃ with hexafluoroisopropanol): δ=8.85 (s, 4H), 7.63 (s, 4H), 7.60 (s, 4H).

### Evaluation I

Each compound according to Synthesis Examples and Reference Synthesis Examples is deposited on a glass substrate, and energy levels of the deposited film is evaluated.

A HOMO energy level may be evaluated by irradiating UV light on the film with AC-2 (Hitachi, Ltd.) or AC-3 (Riken Keiki Co., LTD.) and measuring an amount of photoelectrons according to energy

An LUMO energy level may be calculated by obtaining bandgap energy with UV-Vis spectrometer (Shimadzu Corp.) and using the HOMO energy level.

The results are shown in Tables 1 and 2.

TABLE 1

| | HOMO | LUMO | Energy bandgap |
|---|---|---|---|
| | (eV) | (eV) | (eV) |
| Reference Synthesis Example 1 | 5.52 | 3.44 | 2.08 |
| Synthesis Example 1-1 | 5.63 | 3.54 | 2.09 |
| Synthesis Example 1-2 | 5.70 | 3.61 | 2.09 |
| Synthesis Example 1-3 | 5.70 | 3.56 | 2.14 |
| Reference Synthesis Example 2 | 5.71 | 3.70 | 2.01 |
| Synthesis Example 2-1 | 5.75 | 3.64 | 2.11 |
| Synthesis Example 2-3 | 5.74 | 3.58 | 2.16 |
| Reference Synthesis Example 3 | 5.54 | — | — |
| Synthesis Example 3-1 | 5.57 | 3.44 | 2.13 |
| Reference Synthesis Example 4 | 5.41 | 3.27 | 2.14 |
| Synthesis Example 4-1 | 5.52 | 3.37 | 2.15 |

TABLE 2

| | HOMO | LUMO | Energy |
|---|---|---|---|
| | (eV) | (eV) | bandgap (eV) |
| Synthesis Example 7 | 6.19 | 3.20 | 2.99 |

### Evaluation II

The compounds according to Synthesis Examples and Reference Synthesis Examples are evaluated with respect to a sublimation temperature.

The sublimation temperature is evaluated through thermal weight analysis (TGA) by heating the samples and checking a temperature at which a weight of the samples decreases by 10% relative to the initial weight under high vacuum (less than or equal to about 10 Pa).

The results are shown in Tables 3 to 8.

TABLE 3

| | Tₛ₍₁₀₎(° C.) |
|---|---|
| Reference Synthesis Example 1 | 257 |
| Synthesis Example 1-1 | 244 |
| Synthesis Example 1-2 | 246 |

*Tₛ₍₁₀₎(° C.): Temperature at which a weight of a sample decreases by 10% relative to the initial weight (sublimation temperature)

TABLE 4

| | T_{s(10,} ° C.) |
|---|---|
| Reference Synthesis Example 2 | 237 |
| Synthesis Example 2-1 | 223 |
| Synthesis Example 2-2 | 223 |

TABLE 5

| | T_{s (10,} ° C.) |
|---|---|
| Reference Synthesis Example 3 | 216 |
| Synthesis Example 3-1 | 205 |

TABLE 6

| | T_{s (10,} ° C.) |
|---|---|
| Reference Synthesis Example 5 | 246 |
| Synthesis Example 5-1 | 238 |

TABLE 7

| | T_{s (10,} ° C.) |
|---|---|
| Reference Synthesis Example 6 | 265 |
| Synthesis Example 6-1 | 238 |

TABLE 8

| | T_{s (10,} ° C.) |
|---|---|
| Synthesis Example 7 | 270 |
| (n-type semiconductor) | |

Referring to Tables 3 to 8, the compounds obtained in Synthesis Examples exhibit lower sublimation temperatures compared to the compounds obtained in Reference Synthesis Examples. In addition, the differences between the sublimation temperatures of the p-type semiconductor and the n-type semiconductor are relatively small.

### EXAMPLE: MANUFACTURE OF PHOTOSENSOR

### Example 1-1

Al (10 nm), ITO (100 nm), and Al (8 nm) are sequentially deposited on a glass substrate to form a lower electrode (work function: 4.9 eV) with an AI/ITO/AI structure. On the lower electrode, N,N′-bis(3-methylphenyl)-N,N′-diphenyl-[1,1-biphenyl]-4,4′-diamine is deposited to form a hole auxiliary layer (HOMO: 5.3 to 5.6 eV, LUMO: 2.0 to 2.3 eV). On the hole auxiliary layer, Compound 1-1b obtained in Synthesis Example 1-1 is deposited to form a 10 nm-thick p-type semiconductor layer, and Compound 7-1 obtained in Synthesis Example 7 is deposited to form a 40 nm-thick n-type semiconductor layer, obtaining a bi-layered photosensitive layer. On the photosensitive layer, 4,7-diphenyl-1,10-phenanthroline is deposited to form an electron auxiliary layer (HOMO: 6.1 to 6.4 eV, LUMO: 2.9 to 3.2 eV). On the electron auxiliary layer, magnesium and silver are deposited to form an Mg:Ag upper electrode, and thus manufacturing a photosensor.

### Example 1-2

A photosensor is manufactured in the same manner as in Example 1-1, except that Compound 1-1c obtained in Synthesis Example 1-2 is used instead of Compound 1-1b obtained in Synthesis Example 1-1.

### Example 1-3

A photosensor is manufactured in the same manner as in Example 1-1, except that Compound 1-1d obtained in Synthesis Example 1-3 is used instead of Compound 1-1b obtained in Synthesis Example 1-1.

### Comparative Example 1

A photosensor is manufactured in the same manner as in Example 1-1, except that Compound 1-1 a obtained in Reference Synthesis Example 1 is used instead of Compound 1-1b obtained in Synthesis Example 1-1.

### Example 2-1

A photosensor is manufactured in the same manner as in Example 1-1, except that Compound 1-2b obtained in Synthesis Example 2-1 is used instead of Compound 1-1b obtained in Synthesis Example 1-1.

### Example 2-2

A photosensor is manufactured in the same manner as in Example 1-1, except that Compound 1-2d obtained in Synthesis Example 2-3 is used instead of Compound 1-1b obtained in Synthesis Example 1-1.

### Example 3-1

A photosensor is manufactured in the same manner as in Example 1-1, except that Compound 1-3b obtained in Synthesis Example 3-1 is used instead of Compound 1-1b obtained in Synthesis Example 1-1.

### Example 4-1

A photosensor is manufactured in the same manner as in Example 1-1, except that Compound 1-4b obtained in Synthesis Example 4-1 is used instead of Compound 1-1b obtained in Synthesis Example 1-1.

### Evaluation IV

The light absorption characteristics and electrical characteristics of the photosensors according to Examples and Comparative Examples are evaluated.

The light absorption characteristics are evaluated from a peak absorption wavelength (λₚₑₐₖ) and a full width at half maximum (FWHM) of an absorption spectrum.

The electrical characteristics are evaluated from external quantum efficiency (EQE) and a dark current under a reverse bias voltage. The EQE may be evaluated from EQE at the peak absorption wavelength (λₚₑₐₖ) after allowed to stand at 85° C. for 1 hour, which may be Incident Photon to Current Efficiency (IPCE) at blue (450 nm, B), green (λₚₑₐₖ, G), and 630 nm (red, R) wavelengths at 3 V. The dark current is evaluated by measuring a dark current with current-voltage evaluation device (Keithley K4200 parameter analyzer) after allowed to stand for 1 hour at 85° C. and dividing it by a unit pixel area (0.04 cm²), and dark current density is evaluated from a current flowing when a reverse bias of −3 V is applied thereto. The results are shown in Tables 9 and 10.

TABLE 9

| | | | EQE | |
|---|---|---|---|---|
| | | | (@−3 V, | D.C |
| | λₚₑₐₖ | FWHM | 85° C. 1 h, %) | (mA/ |
| | (nm) | (nm) | (Green) | cm²) |
| Example 1-1 | 534 | 89 | 65.4 | 6.2 × 10⁻⁶ |
| Example 1-2 | 537 | 92 | 56.1 | 5.3 × 10⁻⁶ |
| Example 1-3 | 531 | 87 | 50.6 | 7.1 × 10⁻⁶ |
| Comparative | 528 | 95 | 41.0 | 1.0 × 10⁻⁵ |
| Example 1 | | | | |

TABLE 10

| | | | EQE | |
|---|---|---|---|---|
| | λₚₑₐₖ | FWHM | (@−3 V, 85° C. | D.C |
| | (nm) | (nm) | 1h, %) (Green) | (mA/cm²) |
| Example 2-1 | 592 | 81 | 58.8 | 4.1 × 10⁻⁶ |
| Example 2-2 | 525 | 81 | 58.6 | 3.5 × 10⁻⁶ |
| Example 3-1 | 528 | 73 | 49.6 | 7.5 × 10⁻⁷ |
| Example 4-1 | 519 | 77 | 31.3 | 3.80 × 10⁻⁶ |

Referring to Tables 9 and 10, the photosensors according to Examples exhibit improved optical and electrical characteristics.

While this disclosure has been described in connection with what is presently considered to be practical example embodiments, it is to be understood that inventive concepts are not limited to the disclosed embodiments. On the contrary, are is intended to cover various modifications and equivalent arrangements included within the spirit and scope of the appended claims.

What is claimed is:

1. A sensor-embedded display panel, comprising
a substrate;
a light emitting element on the substrate, the light emitting element including a light emitting layer, and
a photosensor on the substrate, the photosensor including a photosensitive layer in parallel with the light emitting layer along an in-plane direction of the substrate, wherein
the light emitting element and the photosensor comprise respective portions of a first common auxiliary layer,
the first common auxiliary layer is continuous along the in-plane direction of the substrate and under each of the light emitting layer and the photosensitive layer,
the photosensitive layer comprises a fluorine-containing p-type semiconductor and a non-fullerene n-type semiconductor, and
the non-fullerene n-type semiconductor forms a pn junction with the fluorine-containing p-type semiconductor.

2. The sensor-embedded display panel of claim 1, wherein
the fluorine-containing p-type semiconductor is a light absorbing compound comprising an electron donating moiety and an electron accepting moiety, and
the electron donating moiety comprises a fluorine.

3. The sensor-embedded display panel of claim 2, wherein
the fluorine-containing p-type semiconductor is a light absorbing compound represented by any one of Chemical Formulas 1 to 4: 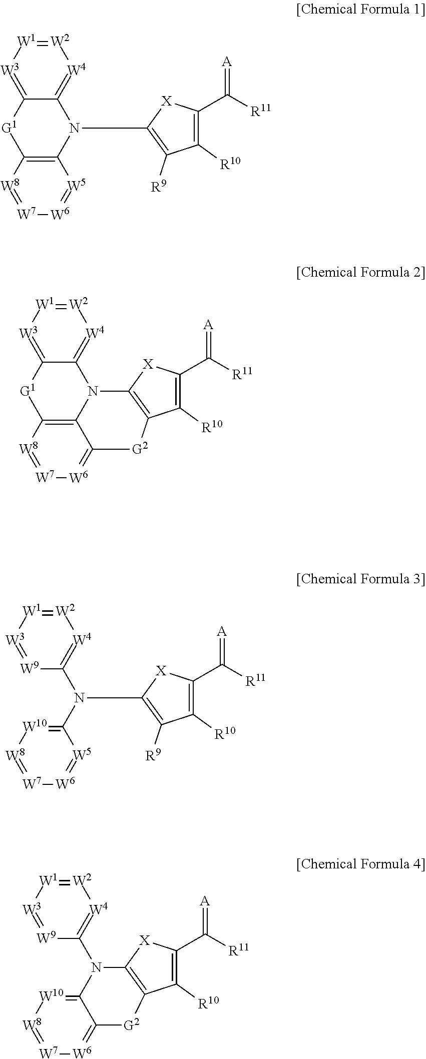
wherein, in Chemical Formulas 1 to 4,
X is O, S, Se, Te, SO, SO₂, CR^{a}R^{b}, SiR^{c}R^{d}, or GeR^{e}R^{f},
W¹ to W¹⁰ are each independently N or CR¹⁰⁰, and at least one of W¹ to W⁸ is CR¹⁰⁰,
G¹ and G² are each independently a single bond, O, S, Se, Te, CR^{g}R^{h}, SiRⁱR^{j}, or GeR^{k}R^{l},
A is an electron accepting moiety,
R⁹ to R¹¹, R¹⁰⁰, and R^{a} to R^{l} are each independently hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
at least one of R¹⁰⁰ and R^{g} to Ris a fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof, and
R⁹ to R¹¹, R¹⁰⁰, and R^{a} to R^{l} are each independently present or an adjacent two of R⁹ to R¹¹, R¹⁰⁰ and R^{a} to R^{l} are linked to each other to form a ring.

4. The sensor-embedded display panel of claim 3, wherein
the fluorine-containing p-type semiconductor is a light absorbing compound represented by any one of Chemical Formulas 1-1 to 4-1: 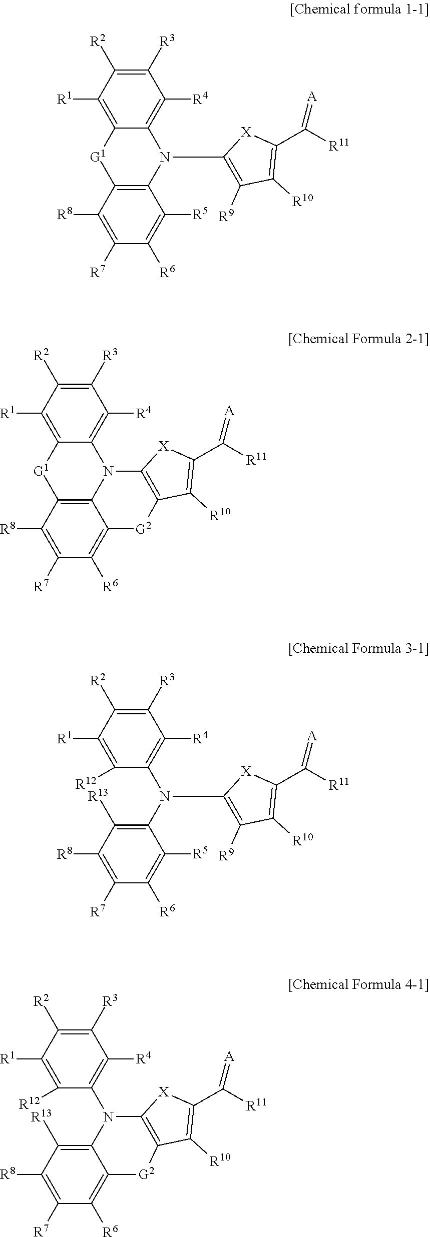
wherein, in Chemical Formulas Chemical Formulas 1-1 to 4-1,
X is O, S, Se, Te, SO, SO₂, CR^{a}R^{b}, SiR^{c}R^{d}, or GeR^{e}R^{f},
G¹ and G² are each independently a single bond, O, S, Se, Te, CR^{a}R^{b}, SiRⁱR^{j}, or GeR^{k}R^{l},
A is a cyclic group comprising C═Z 1 , a halogen, a C1 to C30 haloalkyl group, a cyano group, a dicyanovinyl group, or any combination thereof, wherein Z¹ is O, S, Se, Te, or CR^{m}Rⁿ, wherein R^{m} and Rⁿ are each independently hydrogen, deuterium, a substituted or unsubstituted C1 to C20 alkyl group, a carbonyl group, a cyano group, a dicyanovinyl group, or any combination thereof, and R^{m} and Rⁿ are each independently present or are linked to each other to form a ring,
R¹ to R¹³ and R^{a} to R^{l} are each independently hydrogen, deuterium, a substituted or unsubstituted C1 to C30 alkyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, a nitro group, or any combination thereof,
R¹ to R¹³ and R^{a} to R^{l} are each independently present or an adjacent two of R¹ to R¹³ and R^{a} to R^{l} are linked to each other to form a ring,
at least one of R¹ to R⁸ and R^{g} to R^{l} in Chemical Formula 1-1 or 2-1 comprise a fluorine, and
at least one of R¹ to R⁸, R¹², R¹³, and R^{g} to R^{l} in Chemical Formula 3-1 or 4-1 comprises a fluorine.

5. The sensor-embedded display panel of claim 4, wherein
in Chemical Formula 1-1, Chemical Formula 2-1, or both Chemical Formula 1-1 and Chemical Formula 2-1, at least one of R¹, R², R³, R⁴, R⁵, R⁶, R⁷, R⁸, R^{g}, R^{h}, R^{l}, R^{j}, R^{k}, and R^{l} is fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof, and
in Chemical Formula 3-1, Chemical Formula 4-1, or both Chemical Formula 3-1 and Chemical Formula 4-1, at least one of R¹, R², R³, R⁴, R⁵, R⁶, R⁷, R⁸, R⁹, R¹⁰, R¹¹, R¹², R¹³, R^{g}, R^{h}, Rⁱ, R^{j}, R^{k}, and R^{l} is fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof.

6. The sensor-embedded display panel of claim 4, wherein
at least one of R², R³, R⁶, and R⁷ of Chemical Formulas 1-1 to 4-1 is a fluorine, a fluorine-substituted C1 to C30 alkyl group, a fluorine-substituted C1 to C30 alkoxy group, a fluorine-substituted C1 to C30 alkylthio group, a fluorine-substituted C6 to C30 aryl group, a fluorine-substituted C3 to C30 heterocyclic group, or any combination thereof.

7. The sensor-embedded display panel of claim 3, wherein
A of Chemical Formulas 1 to 4 is a cyclic group comprising C═Z¹, a halogen, a C1 to C30 haloalkyl group, a cyano group, a dicyanovinyl group, or any combination thereof,
wherein Z¹ is O, S, Se, Te, or CR^{m}Rⁿ,
wherein R^{m} and Rⁿ are each independently hydrogen, deuterium, a substituted or unsubstituted C1 to C20 alkyl group, a carbonyl group, a cyano group, a dicyanovinyl group, or any combination thereof, and
R^{m} and Rⁿ are each independently present or are linked to each other to form a ring.

8. The sensor-embedded display panel of claim 7, wherein
A of Chemical Formulas 1 to 4 is a cyclic group represented by any one of Chemical Formulas AA to AE: 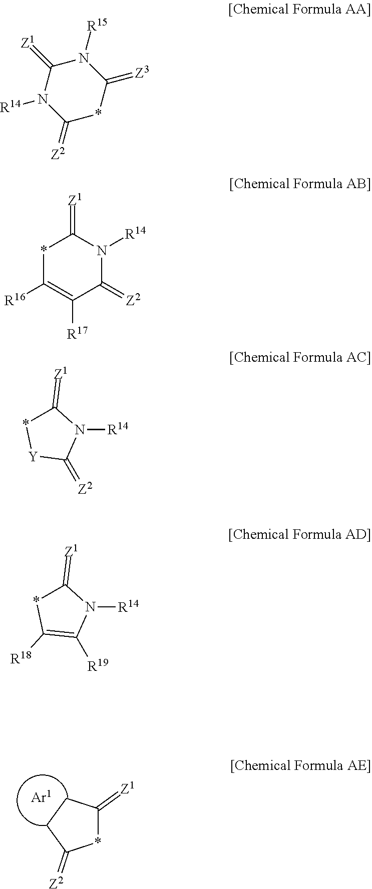
wherein, in Chemical Formulas AA to AE,
Z¹ to Z³ are each independently O, S, Se, Te, or CR^{m}Rⁿ,
wherein R^{m} and Rⁿ are each independently hydrogen, deuterium, a substituted or unsubstituted C1 to C20 alkyl group, a carbonyl group, a cyano group, a dicyanovinyl group, or any combination thereof, and
R^{m} and Rⁿ are each independently present or are linked to each other to form a ring,
Y is O, S, Se, or Te,
Ar¹ is a substituted or unsubstituted C6 to C30 arylene group, a substituted or unsubstituted C3 to C30 cycloalkylene group, a substituted or unsubstituted C3 to C30 cycloalkenylene group, a substituted or unsubstituted C2 to C30 heterocyclic group, or a fused ring thereof,
R¹⁴ to R¹⁹ are each independently hydrogen, deuterium, a substituted or unsubstituted C1 to C20 alkyl group, a substituted or unsubstituted C2 to C30 alkenyl group, a substituted or unsubstituted C1 to C30 alkoxy group, a substituted or unsubstituted C1 to C30 alkylthio group, a substituted or unsubstituted C6 to C30 aryl group, a substituted or unsubstituted C3 to C30 heterocyclic group, a halogen, a cyano group, or any combination thereof,
R¹⁴ to R¹⁹ are each independently present or an adjacent two of R¹⁴ to R¹⁹ are linked to each other to form a ring, and
* is a linking point with any one of Chemical Formulas 1 to 4.

9. The sensor-embedded display panel of claim 1, wherein
a sublimation temperature of the fluorine-containing p-type semiconductor and a sublimation temperature of the non-fullerene n-type semiconductor each are about 100° C. to about 400° C., and
a difference between the sublimation temperature of the fluorine-containing p-type semiconductor and the sublimation temperature of the non-fullerene n-type semiconductor is greater than or equal to about 0° C. and less than about 150° C.,
wherein a sublimation temperature is a temperature at which a weight loss of 10% relative to an initial weight occurs during thermogravimetric analysis at 10 Pa or less.

10. The sensor-embedded display panel of claim 8, wherein
the light emitting layer comprises an organic light emitting material, and
a difference between the fluorine-containing p-type semiconductor, the non-fullerene n-type semiconductor, and the organic light emitting material is greater than or equal to about 0° C. and less than about 150° C.

11. The sensor-embedded display panel of claim 1, wherein
a difference between a HOMO energy level of the fluorine-containing p-type semiconductor and a HOMO energy level of the first common auxiliary layer is greater than or equal to about 0 eV and less than about 1.0 eV.

12. The sensor-embedded display panel of claim 1, wherein
the non-fullerene n-type semiconductor is a transparent semiconductor that does not substantially absorb light in a visible wavelength spectrum, and
the photosensitive layer consists of the fluorine-containing p-type semiconductor and the non-fullerene n-type semiconductor.

13. The sensor-embedded display panel of claim 1, wherein
the photosensitive layer comprises a first photosensitive layer and a second photosensitive layer,
the first photosensitive layer consists of the fluorine-containing p-type semiconductor,
the second photosensitive layer consists of the non-fullerene n-type semiconductor,
and the first photosensitive layer is closer to the first common auxiliary layer than the second photosensitive layer.

14. The sensor-embedded display panel of claim 1, wherein
the light emitting element comprises a first light emitting element, a second light emitting element, or and a third light emitting element,
the first light emitting element, the second light emitting element, and the third light emitting element are configured to emit light of different wavelength spectra from each other, and
the photosensor is configured to absorb reflected emitted light and convert absorbed reflected emitted light into an electrical signal,
the reflected emitted light is light emitted from at least one of the first light emitting element, the second light emitting element, or the third light emitting elements and then reflected by a recognition target to the photosensor and convert the absorbed light into an electrical signal.

15. The sensor-embedded display panel of claim 1, further comprising:
a common electrode configured to apply a common voltage to the light emitting element and the photosensor.

16. The sensor-embedded display panel of claim 15, wherein
the light emitting element and the photosensor further comprise respective portions of a second common auxiliary layer,
the second common auxiliary layer is between the common electrode and the light emitting layer and between the common electrode and the photosensitive layer, and
the second common auxiliary layer is continuous along the in-plane direction of the substrate and on the light emitting layer and the photosensitive layer.

17. The sensor-embedded display panel of claim 16, wherein
a difference between a LUMO energy level of the non-fullerene n-type semiconductor and a LUMO energy level of the second common auxiliary layer is greater than or equal to about 0 eV and less than about 1.0 eV.

18. The sensor-embedded display panel of claim 1, wherein
the sensor-embedded display panel comprises a display area and a non-display area excluding the display area,
the display area is configured to display a color, and
a non-display area excluding the display area,
wherein the light emitting element is in the display area, and
the photosensor is in the non-display area.

19. The sensor-embedded display panel of claim 18, wherein
the light emitting element comprises a first light emitting element configured to emit light of a red wavelength spectrum, a second light emitting element configured to emit light of a green wavelength spectrum, and a third light emitting element configured to emit light of a blue emission spectrum,
the display area comprises a plurality of first subpixels configured to display red, a plurality of second subpixels configured to display green, and a plurality of third subpixels configured to display blue,
the plurality of first subpixels include the first light emitting element,
the plurality of second subpixels include the second light emitting element,
the plurality of third subpixels include the third light emitting element, and
the photosensor is between two of the first subpixel, the second subpixel, and the third subpixel.

20. An electronic device comprising:
the sensor-embedded display panel of claim 1.
